(19) United States
(12) Patent Application Publication
(10) Pub. No.: US 2026/0018852 A1
(43) Pub. Date: Jan. 15, 2026

(54) SEMICONDUCTOR LIGHT EMITTING DEVICE AND METHOD FOR MANUFACTURING SEMICONDUCTOR LIGHT EMITTING DEVICE

(71) Applicant: ROHM CO., LTD., Kyoto (JP)

(72) Inventor: Akito SHINODA, Kyoto-shi (JP)

(73) Assignee: ROHM CO., LTD., Kyoto (JP)

(21) Appl. No.: 19/330,363

(22) Filed: Sep. 16, 2025

Related U.S. Application Data
(63) Continuation of application No. PCT/JP2024/006346, filed on Feb. 21, 2024.

(30) Foreign Application Priority Data
Mar. 24, 2023 (JP) 2023-048478

(51) Int. Cl. H01S 5/02208

(52) U.S. Cl. CPC H01S 5/02208

(57) ABSTRACT

A semiconductor light emitting device is provided with: a substrate; an end surface emitting element that is mounted on the substrate; a cap that houses the end surface emitting element; and an adhesive that bonds the cap and the substrate to each other. The substrate is provided with a substrate through hole at a position where the substrate overlaps with the adhesive in a plan view. The semiconductor light emitting device comprises a bonding pattern that is formed on the substrate so as to surround the end surface emitting element in a plan view. The adhesive is provided on the bonding pattern and bonds the bonding pattern and the cap to each other. A pattern through hole, which is in communication with the substrate through hole, is formed in the bonding pattern. Some of the adhesive is in the pattern through hole.

### CROSS-REFERENCE TO RELATED APPLICATIONS

This application is a continuation of, and claims the benefit of priority from International Application No. PCT/JP2024/006346, filed on Feb. 21, 2024, which claims the benefit of priority from Japanese Patent Application No. 2023-048478, filed on Mar. 24, 2023, the entire contents of each are incorporated herein by reference.

### BACKGROUND

### 1. Field

The present disclosure relates to a semiconductor light emitting device and a method for manufacturing a semiconductor light emitting device.

### 2. Description of Related Art

JP2021-174820A describes an example of a semiconductor light emitting device that includes a substrate, a semiconductor light emitting element mounted on the substrate, and a cap mounted on the substrate to accommodate the semiconductor light emitting element. In such a semiconductor light emitting device, the cap is bonded to the substrate, for example, by an adhesive.

### BRIEF DESCRIPTION OF THE DRAWINGS

FIG. 1 is a perspective view showing a first embodiment of a semiconductor light emitting device.

FIG. 2 is a schematic plan view showing the internal structure of the semiconductor light emitting device shown in FIG. 1.

FIG. 3 is a bottom view of the semiconductor light emitting device shown in FIG. 1.

FIG. 4 is a schematic cross-sectional view showing the cross-sectional structure of the semiconductor light emitting device taken along line F4-F4 shown in FIG. 2.

FIG. 5 is a schematic cross-sectional view showing the cross-sectional structure of the semiconductor light emitting device taken along line F5-F5 shown in FIG. 2.

FIG. 6 is an enlarged view of FIG. 5 showing a cross section of a pattern through hole in an adhesion pattern and a substrate through hole.

FIG. 7 is a schematic cross-sectional view showing an exemplary manufacturing step of the semiconductor light emitting device in accordance with the first embodiment.

FIG. 8 is a schematic cross-sectional view showing an exemplary manufacturing step following the step of FIG. 7.

FIG. 9 is a schematic cross-sectional view showing an exemplary manufacturing step following the step of FIG. 8.

FIG. 10 is a schematic cross-sectional view showing an exemplary manufacturing step following the step of FIG. 9.

FIG. 11 is a schematic plan view showing the internal structure of a semiconductor light emitting device in accordance with a second embodiment.

FIG. 12 is an enlarged cross-sectional view showing a bonding structure of an adhesion pattern and a cap of the semiconductor light emitting device in the second embodiment.

FIG. 13 is a schematic cross-sectional view showing an exemplary manufacturing step of the semiconductor light emitting device in the second embodiment.

FIG. 14 is a schematic cross-sectional diagram showing an exemplary manufacturing step following the step of FIG. 13.

FIG. 15 is a schematic cross-sectional diagram showing an exemplary manufacturing step following the step of FIG. 14.

FIG. 16 is a schematic cross-sectional diagram showing an exemplary manufacturing step following the step of FIG. 15.

FIG. 17 is an enlarged cross-sectional view showing a bonding structure of an adhesion pattern and a cap in a modified example of a semiconductor light emitting device.

FIG. 18 is an enlarged cross-sectional view showing a bonding structure of an adhesion pattern and a cap in a modified example of a semiconductor light emitting device.

FIG. 19 is an enlarged cross-sectional view showing a bonding structure of an adhesion pattern and a cap in a modified example of a semiconductor light emitting device.

FIG. 20 is an enlarged cross-sectional view showing a pattern through hole in an adhesion pattern and a substrate through hole in a modified example of a semiconductor light emitting device.

FIG. 21 is an enlarged cross-sectional view showing a pattern through hole in an adhesion pattern and a substrate through hole in a modified example of a semiconductor light emitting device.

FIG. 22 is a schematic plan view showing the internal structure of a semiconductor light emitting device in a modified example.

FIG. 23 is a cross-sectional view showing a bonding structure of an adhesion pattern and a cap in a modified example of a semiconductor light emitting device.

FIG. 24 is a schematic plan view showing the internal structure of a semiconductor light emitting device of a modified example.

FIG. 25 is a schematic plan view showing the internal structure of a semiconductor light emitting device of a modified example.

FIG. 26 is an enlarged cross-sectional view showing a pattern through hole in an adhesion pattern and a substrate through hole in a modified example of a semiconductor light emitting device.

FIG. 27 is an enlarged cross-sectional view showing a pattern through hole in an adhesion pattern and a substrate through hole of a semiconductor light emitting device in a modified example.

FIG. 28 is an enlarged cross-sectional view showing a bonding structure of an adhesion pattern and a cap in a modified example of a semiconductor light emitting device.

FIG. 29 is an enlarged cross-sectional view showing a bonding structure of an adhesion pattern and a cap in a modified example of a semiconductor light emitting device.

FIG. 30 is a schematic plan view showing the internal structure of a semiconductor light emitting device in a modified example.

FIG. 31 is an enlarged cross-sectional view showing a bonding structure of an adhesion pattern and a cap in a modified example of a semiconductor light emitting device.

FIG. 32 is an enlarged cross-sectional view showing a bonding structure of an adhesion pattern and a cap in a modified example of a semiconductor light emitting device.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

### First Embodiment

### Overall Configuration of Semiconductor Light Emitting Device

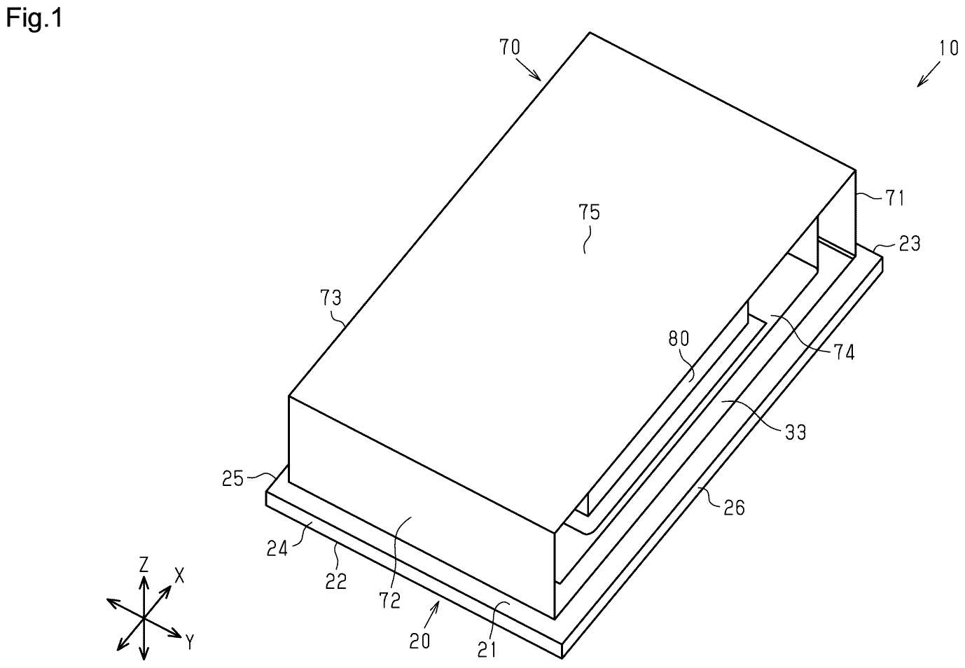

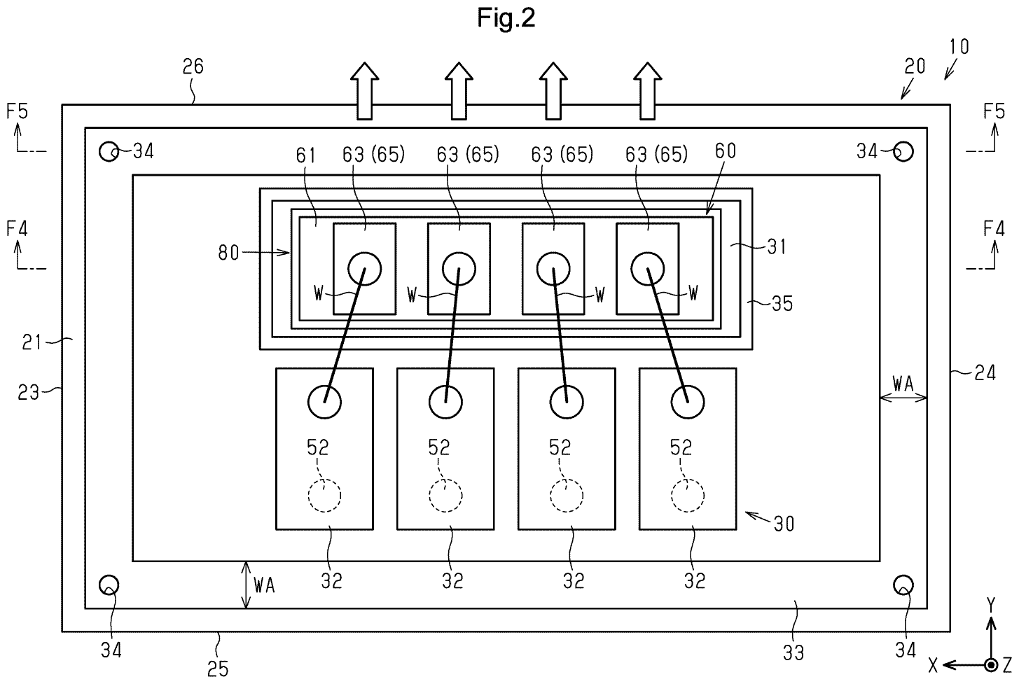

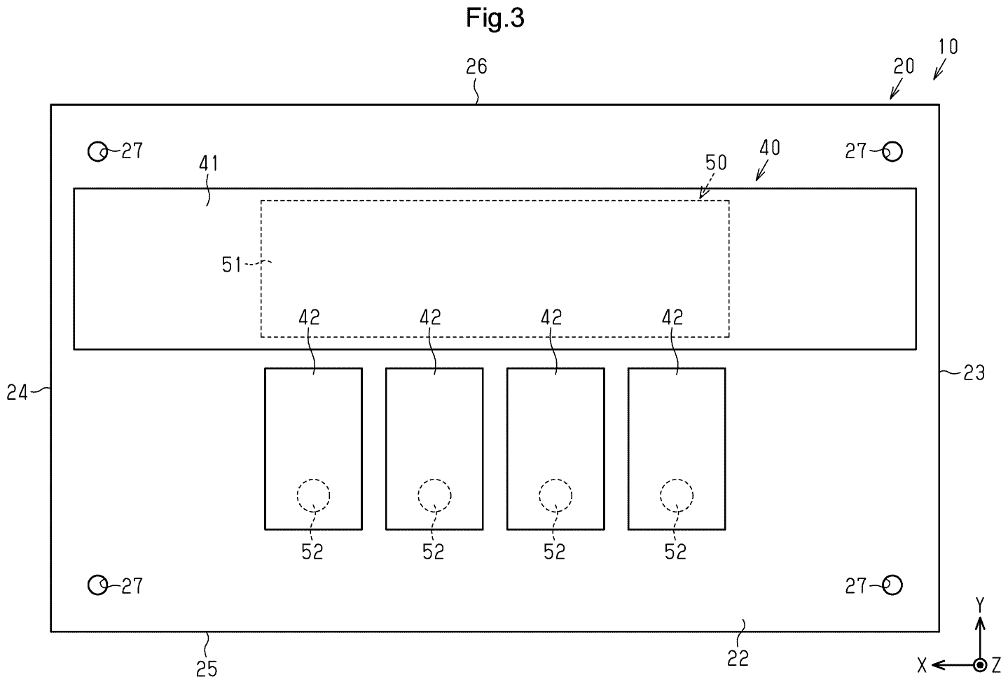

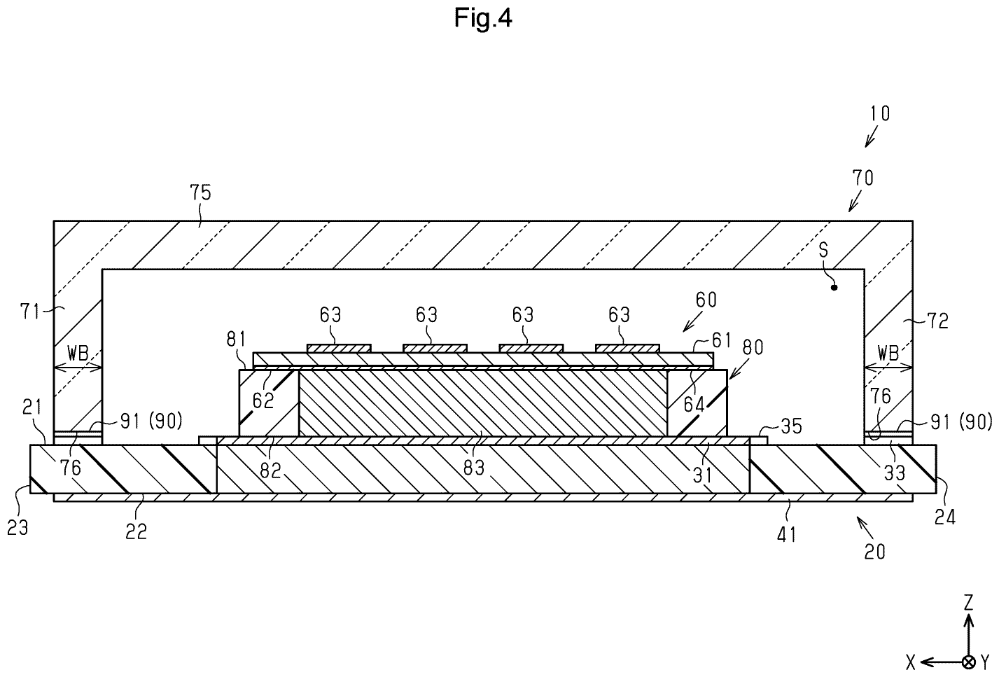

An overall configuration of a semiconductor light emitting device 10 in accordance with a first embodiment will now be described with reference to FIGS. 1 to 4. FIG. 1 is a perspective view of the semiconductor light emitting device 10. FIG. 2 is a plan view showing the internal structure of the semiconductor light emitting device 10. FIG. 3 is a bottom view of the semiconductor light emitting device 10. FIG. 4 is a cross-sectional view showing the structure of the semiconductor light emitting device 10 taken along line F4-F4 in FIG. 2. FIG. 4 does not show wires W, which will be described later, to facilitate understanding of the drawing.

As shown in FIG. 1, the semiconductor light emitting device 10 includes a substrate 20, an edge-emitting light emitting element 60 (refer to FIG. 2), and a cap 70. The substrate 20 has the form of a rectangular plate. The edge-emitting light emitting element 60 is mounted on the substrate 20. The cap 70 is mounted on the substrate 20 and accommodates the edge-emitting light emitting element 60. The thickness-wise direction of the substrate 20 will be referred to as “the Z-direction”. Two directions orthogonal to each other and to the Z-direction will be referred to as “the X-direction” and “the Y-direction.” In this specification, “plan view” refers to a view of the semiconductor light emitting device 10 as viewed in the thickness-wise direction of the substrate 20 (the Z-direction). In the first embodiment, the substrate 20 is rectangular in plan view, with the X-direction corresponding to its longitudinal direction, and the Y-direction corresponding to its lateral direction.

The substrate 20 includes a substrate front surface 21, a substrate back surface 22, and first to fourth substrate side surfaces 23 and 26. The substrate front surface 21 and the substrate back surface 22 face away from each other in the Z-direction. The first to fourth substrate side surfaces 23 to 26 intersect the substrate front surface 21 and the substrate back surface 22. In the first embodiment, the substrate front surface 21 and the substrate back surface 22 are both flat and are orthogonal to the Z-direction. In an example, the first to fourth substrate side surfaces 23 to 26 are flat and are orthogonal to the substrate front surface 21 and the substrate back surface 22. The first substrate side surface 23 and the second substrate side surface 24 define two end surfaces of the substrate 20 in the X-direction. The third substrate side surface 25 and the fourth substrate side surface 26 define two end surfaces of the substrate 20 in the Y-direction.

The substrate 20 is formed from, for example, a material that does not allow for passage of ultraviolet rays. In an example, the substrate 20 is formed from glass epoxy resin. The substrate 20 may be formed from a material including ceramic. Examples of the material including ceramic include aluminum nitride (AlN) or alumina (Al₂O₃). When the substrate 20 is formed from a material including ceramic, the heat dissipation efficiency of the substrate 20 is increased. This avoids an excessive increase in the temperature of the edge-emitting light emitting element 60.

As shown in FIG. 2, the edge-emitting light emitting element 60 is, for example, a laser diode that emits light having a predetermined wavelength and is used as a light source of the semiconductor light emitting device 10. The edge-emitting light emitting element 60 is an edge-emitting type laser element. Although the structure of the edge-emitting light emitting element 60, as the edge-emitting type laser element, is not particularly limited, in the first embodiment, a Fabry-Perot laser diode element is used. In an example, in plan view, the edge-emitting light emitting element 60 is configured to emit light toward the fourth substrate side surface 26. The edge-emitting light emitting element 60 corresponds to a “semiconductor light emitting element.” In addition, the edge-emitting light emitting element 60 corresponds to “a semiconductor laser element.”

The semiconductor light emitting device 10 includes multiple (in the first embodiment, five) front electrodes 30 formed on the substrate front surface 21 of the substrate 20. The front electrodes 30 are arranged separately from each other. The front electrodes 30 are formed of, for example, a copper foil. The material of the front electrodes 30 is not limited to copper (Cu) and may include at least one of aluminum (Al), nickel (Ni), palladium (Pd), silver (Ag), and gold (Au).

The front electrodes 30 include an element front electrode 31 and multiple (in the first embodiment, four) wire connection electrodes 32. The element front electrode 31 and the wire connection electrodes 32 are each electrically connected to the edge-emitting light emitting element 60.

In the Y-direction, the element front electrode 31 is located closer to the fourth substrate side surface 26 than the center of the substrate front surface 21 is. The element front electrode 31 is rectangular with the X-direction corresponding to its longitudinal direction, and the Y-direction corresponding to its lateral direction. In an example, the dimension of the element front electrode 31 in the X-direction is greater than twice and less than three times the dimension of the element front electrode 31 in the Y-direction. In an example, the dimension of the element front electrode 31 in the X-direction is greater than ½ of the dimension of the substrate front surface 21 in the X-direction.

In plan view, the element front electrode 31 is surrounded by a resist pattern 35 having the form of a rectangular frame. The resist pattern 35 is, for example, formed from an insulating material.

The wire connection electrodes 32 are located closer to the third substrate side surface 25 than the element front electrode 31 is. In other words, the wire connection electrodes 32 are located closer to the third substrate side surface 25 than the edge-emitting light emitting element 60 is. The wire connection electrodes 32 are located at the same position in the Y-direction and spaced apart from each other in the X-direction. Each wire connection electrode 32 is rectangular in plan view, with the Y-direction corresponding to its longitudinal direction, and the X-direction corresponding to its lateral direction. As viewed in the Y-direction, the wire connection electrodes 32 overlap the element front electrode 31.

The semiconductor light emitting device 10 includes a submount substrate 80 mounted on the element front electrode 31. In an example, the submount substrate 80 is die-bonded to the element front electrode 31. The submount substrate 80 supports the edge-emitting light emitting element 60 and is, for example, formed from a material including ceramic. Examples of the material including ceramic include AlN and Al₂O₃. When the submount substrate 80 is formed from the material including ceramic, the heat dissipation efficiency of the submount substrate 80 is increased. Thus, heat readily transfers from the edge-emitting light emitting element 60 to the substrate 20 through the submount substrate 80. This avoids an excessive increase in the temperature of the edge-emitting light emitting element 60.

The material forming the submount substrate 80 may be changed in any manner. In an example, the submount substrate 80 may be formed from a highly conductive metal material with high heat dissipation efficiency. Examples of such a metal material include Ag and Cu. In an example, the submount substrate 80 may be formed of a rectangular plate of Cu. In another example, the submount substrate 80 may be formed from a material including silicon (Si).

As shown in FIGS. 2 and 4, the submount substrate 80 has the form of a rectangular plate. In an example, the submount substrate 80 is rectangular in plan view, with the X-direction corresponding to its longitudinal direction, and the Y-direction corresponding to its lateral direction. In an example, in plan view, the submount substrate 80 is slightly smaller than the element front electrode 31.

As shown in FIG. 4, the submount substrate 80 is greater in thickness than the substrate 20. The thickness of the submount substrate 80 may be changed in any manner and may be, for example, less than or equal to the thickness of the substrate 20.

The submount substrate 80 includes a front surface 81 and a back surface 82 that face away from each other in the Z-direction. In the first embodiment, the front surface 81 and the back surface 82 are both flat and are orthogonal to the Z-direction. The front surface 81 and the substrate front surface 21 face in the same direction. The back surface 82 and the substrate back surface 22 face in the same direction. The edge-emitting light emitting element 60 is mounted on the front surface 81 of the submount substrate 80. In an example, the edge-emitting light emitting element 60 is die-bonded to the front surface 81 of the submount substrate 80.

A through interconnect 83 extends through the submount substrate 80 in the thickness-wise direction. The through interconnect 83 is an interconnect that electrically connects the edge-emitting light emitting element 60 and the element front electrode 31. The through interconnect 83 is formed from a material including, for example, Cu. The material forming the through interconnect 83 is not limited to Cu and may include at least one of titanium (Ti), tungsten (W), and Al. The number of through interconnects 83 may be changed in any manner. For example, multiple through interconnects 83 may be arranged.

When the submount substrate 80 is formed from a conductive material such as Cu, the through interconnect 83 may be omitted. That is, the edge-emitting light emitting element 60 and the element front electrode 31 are electrically connected to each other by the conductive submount substrate 80.

As shown in FIGS. 2 and 4, the edge-emitting light emitting element 60, which is mounted on the submount substrate 80, has the form of a rectangular plate. The edge-emitting light emitting element 60 is rectangular in plan view, with the X-direction corresponding to its longitudinal direction, and the Y-direction corresponding to its lateral direction. In an example, in plan view, the edge-emitting light emitting element 60 is slightly smaller than the submount substrate 80.

The edge-emitting light emitting element 60 is smaller in thickness than the submount substrate 80. The edge-emitting light emitting element 60 is smaller in thickness than the substrate 20. The thickness of the edge-emitting light emitting element 60 may be changed in any manner and may be, for example, greater than or equal to the thickness of the substrate 20 or greater than or equal to the thickness of the submount substrate 80.

The edge-emitting light emitting element 60 includes an element front surface 61 and an element back surface 62 that face away from each other in the Z-direction. In the first embodiment, the element front surface 61 and the element back surface 62 are both flat and are orthogonal to the Z-direction. The edge-emitting light emitting element 60 includes multiple (in the first embodiment, four) element electrodes 63 formed on the element front surface 61 and a back electrode 64 defining the element back surface 62. The edge-emitting light emitting element 60 includes light emitters 65 respectively arranged for the element electrodes 63. In plan view, the element electrodes 63 are separated from each other in the X-direction. Therefore, the multiple (in the first embodiment, four) light emitters 65 are arranged in the X-direction. As indicated by white arrows in FIG. 2, in plan view, the light emitters 65 are each configured to emit a laser beam toward the fourth substrate side surface 26.

Each element electrode 63 is rectangular in plan view, with the Y-direction corresponding to its longitudinal direction, and the X-direction corresponding to its lateral direction. In the first embodiment, the element electrodes 63 each include the anode electrode of the corresponding one of the light emitters 65. The back electrode 64 is, for example, formed on the entirety of the element back surface 62 of the edge-emitting light emitting element 60. In the first embodiment, the back electrode 64 includes the cathode electrode that is common to the light emitters 65. The element electrodes 63 and the back electrode 64 are formed from, for example, Au. The material forming the element electrodes 63 and the back electrode 64 are not limited to Au and may include at least one of Al, Ni, Pd, Ag, and Cu.

The edge-emitting light emitting element 60 is mounted on the submount substrate 80 by a conductive bonding material, which is not shown in the drawings. Thus, the back electrode 64 is electrically connected to the submount substrate 80 (the through interconnect 83) by the conductive bonding material. The back electrode 64 is electrically connected to the element front electrode 31 by the through interconnect 83. The conductive bonding material includes, for example, solder paste and silver paste.

As shown in FIG. 2, the semiconductor light emitting device 10 includes multiple wires W separately electrically connecting the light emitters 65 and the wire connection electrodes 32. The wires W are, for example, bonding wires. The wires W are, for example, formed from a material including Au. The wires W may be formed from a material including at least one of Cu, Ag, and Al instead of Au.

As shown in FIG. 3, the semiconductor light emitting device 10 includes multiple (in the first embodiment, five) back electrodes 40 formed on the substrate back surface 22 of the substrate 20. The back electrodes 40 are arranged separately from each other. The back electrodes 40 are formed from, for example, a copper foil. The material forming the back electrodes 40 is not limited to Cu and may include at least one of Al, Ni, Pd, Ag, and Au.

The back electrodes 40 include an element back electrode 41 and multiple (in the first embodiment, four) wire back electrodes 42. The element back electrode 41 is electrically connected to the element front electrode 31 (refer to FIG. 2) formed on the substrate front surface 21. The wire back electrodes 42 are separately electrically connected the wire connection electrodes 32 (refer to FIG. 2) of the substrate front surface 21.

In plan view, the element back electrode 41 overlaps the element front electrode 31. The element back electrode 41 is rectangular in plan view, with the X-direction corresponding to its longitudinal direction, and the Y-direction corresponding to its lateral direction. The dimension of the element back electrode 41 in the X-direction is larger than the dimension of the element front electrode 31 in the X-direction.

The wire back electrodes 42 overlap the wire connection electrodes 32 in plan view. In an example, in plan view, the wire back electrodes 42 are identical in shape and size to the wire connection electrodes 32.

The semiconductor light emitting device 10 includes multiple through interconnects 50, separately electrically connecting the front electrodes 30 and the back electrodes 40. The through interconnects 50 extend through the substrate 20 in the thickness-wise direction. The through interconnects 50 are formed from, for example, Cu. The material forming the through interconnects 50 is not limited to Cu and may include at least one of W, Ti, and Al.

The through interconnects 50 include an element through interconnect 51 electrically connecting the element front electrode 31 (refer to FIG. 2) and the element back electrode 41 and multiple (in the first embodiment, four) wire through interconnects 52, separately electrically connecting the wire connection electrodes 32 (refer to FIG. 2) and the wire back electrodes 42.

The element through interconnect 51 is rectangular in plan view, with the X-direction corresponding to its longitudinal direction, and the Y-direction corresponding to its lateral direction. In plan view, the element through interconnect 51 is arranged in the center of the element front electrode 31 (the element back electrode 41) in the X-direction and the Y-direction. In plan view, the shape of the element through interconnect 51 may be changed in any manner. The number of element through interconnects 51 may be changed in any manner. In an example, multiple element through interconnects 51 may be arranged. For example, the element through interconnects 51 overlap both the element front electrode 31 and the element back electrode 41 in plan view.

The wire through interconnects 52 may be circular in plan view. Each wire through interconnect 52 is located on one of the two ends of the wire connection electrode 32 (the wire back electrode 42) in the Y-direction that is located farther from the element front electrode 31 (the element back electrode 41). In plan view, the shape of the wire through interconnect 52 may be changed in any manner. Multiple wire through interconnects 52 may be arranged for each of the wire connection electrodes 32 (the wire back electrodes 42). In this case, for example, the wire through interconnects 52 arranged for each of the wire connection electrodes 32 (the wire back electrodes 42) overlap both the wire connection electrodes 32 and the wire back electrodes 42 in plan view.

As shown in FIG. 2, the semiconductor light emitting device 10 includes an adhesion pattern 33 formed on the substrate front surface 21. In plan view, the adhesion pattern 33 is frame-shaped and surrounds the front electrodes 30. In an example, the adhesion pattern 33 is rectangular, with the X-direction corresponding to its longitudinal direction and the Y-direction corresponding to its lateral direction. In an example, the outer edge of the adhesion pattern 33 is slightly smaller than the outer edge of the substrate 20. In an example, the adhesion pattern 33 has a width-wise dimension WA that is uniform along the entire perimeter. In plan view, the width-wise dimension WA of the adhesion pattern 33 is orthogonal to the direction in which the adhesion pattern 33 extends.

The adhesion pattern 33 is formed from, for example, a metal layer. In an example, the adhesion pattern 33 is formed from the same material as the front electrodes 30. The adhesion pattern 33 and the front electrodes 30 may be formed from different materials. In an example, the adhesion pattern 33 may be formed of an insulation layer. The adhesion pattern 33 may be, for example, formed from the same material as the resist pattern 35.

Since the adhesion pattern 33 is formed of a metal layer or an insulation layer, the adhesion pattern 33 slightly projects from the substrate front surface 21 in the Z-direction. In the first embodiment, for example, the adhesion pattern 33 is equal in thickness to the front electrodes 30. The thickness of the adhesion pattern 33 may be changed in any manner and may be, for example, greater than or smaller than the thickness of the front electrode 30.

An adhesive 90 (refer to FIG. 4) is applied to the adhesion pattern 33. In an example, in plan view, the adhesive 90 extends along the entire perimeter of the adhesion pattern 33. The adhesion pattern 33 restricts extension of the adhesive 90 beyond the adhesion pattern 33.

As shown in FIGS. 1 and 4, a cap 70 is fixed to the adhesion pattern 33 by the adhesive 90. The cap 70 is box-shaped and is open toward the substrate 20 in the Z-direction. The cap 70 is formed from, for example, a material that allows for passage of ultraviolet rays. In an example, the cap 70 is formed from a glass material. Alternatively, the cap 70 may be formed from a resin material instead of a glass material. The resin material includes, for example, an acrylic resin and an epoxy resin. The cap 70 may be formed from at least one of metal and ceramic. The metal includes, for example, aluminum, iron, and copper. The ceramic includes, for example, AlN and Al₂O₃.

As shown in FIG. 1, in plan view, the cap 70 includes first to fourth side walls 71 to 74 having the form of a rectangular frame in plan view, and an upper wall 75 covering one end of the opening defined by the first to fourth side walls 71 to 74 in the Z-direction. In an example, the first to fourth side walls 71 to 74 and the upper wall 75 are formed integrally. The first side wall 71 and the second side wall 72 define two end side walls of the cap 70 in the X-direction. The third side wall 73 and the fourth side wall 74 define two end side walls of the cap 70 in the Y-direction. The first side wall 71 is one of the two end side walls of the cap 70 in the X-direction located closer to the first substrate side surface 23 of the substrate 20. The second side wall 72 is one of the two end side walls of the cap 70 in the X-direction located closer to the second substrate side surface 24 of the substrate 20. The third side wall 73 is one of the two end side walls of the cap 70 in the Y-direction located closer to the third substrate side surface 25 of the substrate 20. The fourth side wall 74 is one of the two end side walls of the cap 70 in the Y-direction located closer to the fourth substrate side surface 26 of the substrate 20. In an example, when the cap 70 is formed from a glass material or a resin material, the first to third side walls 71 to 73 and the upper wall 75 are translucent, and the fourth side wall 74 is transparent. A laser beam emitted from the edge-emitting light emitting element 60 passes through the fourth side wall 74 and exits the semiconductor light emitting device 10. In an example, when the cap 70 is formed from metal or ceramic, the fourth side wall 74 has an opening and is provided with a window member closing the opening. The window member allows for passage of the laser beam from the edge-emitting light emitting element 60.

### Bonding Structure of Cap and Adhesion Pattern

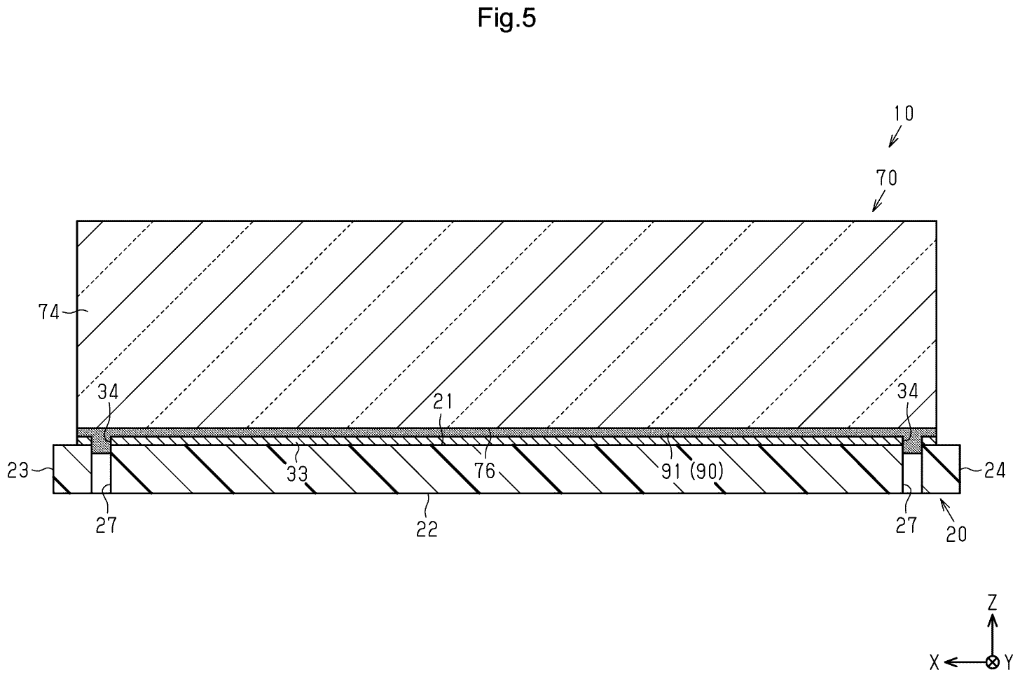

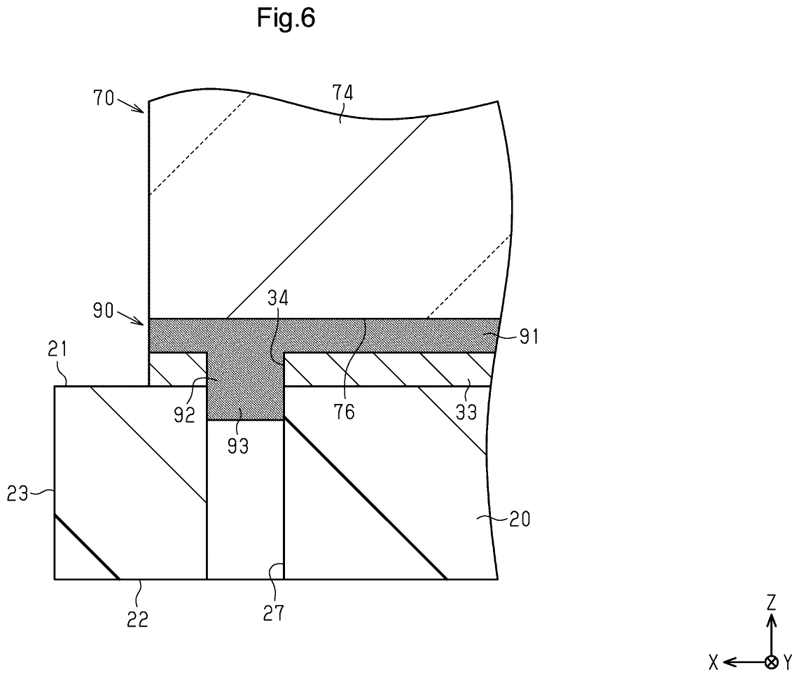

With reference to FIGS. 2 to 6, the bonding structure of the cap 70 and the adhesion pattern 33 will be described. FIG. 5 is a cross-sectional view showing the bonding structure of the fourth side wall 74 of the cap 70 and the adhesion pattern 33 with the adhesive 90. FIG. 6 is a cross-sectional view showing a pattern through hole 34 and a substrate through hole 27 shown in FIG. 5.

As shown in FIG. 5, the fourth side wall 74 of the cap 70 has an open-end surface 76. The open-end surface 76 is an end surface of the fourth side wall 74 located close to the substrate 20. In other words, the open-end surface 76 is a distal surface of the fourth side wall 74. In the first embodiment, the open-end surface 76 is flat and is orthogonal to the Z-direction. In other words, the open-end surface 76 includes a flat surface. As shown in FIG. 4, the first side wall 71 and the second side wall 72 also include an open-end surface 76. Although not shown in FIG. 4, the third side wall 73 also includes an open-end surface 76. The open-end surfaces 76 of the first to fourth side walls 71 to 74 of the cap 70 are opposed to the adhesion pattern 33 in the Z-direction. The open-end surfaces 76 of the first to fourth side walls 71 to 74 have the form of a rectangular frame in plan view.

As shown in FIG. 4, the first to fourth side walls 71 to 74 have the same width-wise dimension WB. The width-wise dimension WB of the first side wall 71 and the width-wise dimension WB of the second side wall 72 are defined by, for example, the dimension of the first side wall 71 in the X-direction and the dimension of the second side wall 72 in the X-direction. The width-wise dimension WB of the third side wall 73 and the width-wise dimension WB of the fourth side wall 74 are defined by, for example, the dimension of the third side wall 73 in the Y-direction and the dimension of the fourth side wall 74 in the Y-direction.

In an example, the width-wise dimensions WB of the first to fourth side walls 71 to 74 are equal to the width-wise dimension WA (refer to FIG. 2) of the adhesion pattern 33. More specifically, the width-wise dimension WB of each of the first side wall 71 and the second side wall 72 is equal to the width-wise dimension WA (in FIG. 4, the dimension in the X-direction) of a portion the adhesion pattern 33 opposed to the first side wall 71 and the second side wall 72 in the Z-direction. The width-wise dimension WB of each of the third side wall 73 and the fourth side wall 74 is equal to the width-wise dimension WA of a portion of the adhesion pattern 33 opposed to the third side wall 73 and the fourth side wall 74 in the Z-direction.

It is considered that the width-wise dimension WB of the first side wall 71 is equal to the adhesion pattern 33 in the width-wise dimension WA when the difference between the width-wise dimension WB of the first side wall 71 and the width-wise dimension WA of the adhesion pattern 33 is, for example, within 10% of the width-wise dimension WA of the adhesion pattern 33. The same applies to the relationship between the width-wise dimension WB of each of the second side wall 72, the third side wall 73, and the fourth side wall 74 and the width-wise dimension WA of the adhesion pattern 33.

When the cap 70 is bonded to the adhesion pattern 33, the cap 70 and the substrate 20 form a sealed space S. The sealed space S accommodates the front electrodes 30, the wires W (refer to FIG. 2), the submount substrate 80, and the edge-emitting light emitting element 60. In an example, the sealed space S is defined by the substrate front surface 21, the inner surfaces of the first to fourth side walls 71 to 74 and the lower surface of the upper wall 75 of the cap 70.

As shown in FIG. 5, in plan view, the substrate 20 has substrate through holes 27 at a position overlapping the adhesive 90. The substrate through holes 27 extend through the substrate 20 in the Z-direction. In an example, as shown in FIG. 3, multiple (in the first embodiment, four) substrate through holes 27 are arranged. The substrate through holes 27 are arranged separately from each other. The substrate through holes 27 overlap the adhesion pattern 33 in plan view. The substrate through holes 27 are each circular in plan view. The substrate through holes 27 and the back electrodes 40 are located at different positions.

As shown in FIGS. 2 and 5, the adhesion pattern 33 has pattern through holes 34. The pattern through holes 34 extend through the adhesion pattern 33 in the Z-direction. As shown in FIG. 5, the adhesion pattern 33 communicates with the substrate through holes 27. In other words, in plan view, the pattern through holes 34 overlap the substrate through holes 27.

As shown in FIG. 2, multiple (in the first embodiment, four) pattern through holes 34 are arranged. In the first embodiment, the number of pattern through holes 34 is equal to the number of substrate through holes 27. The pattern through holes 34 are separately located at four corners of the adhesion pattern 33, which has the form of a rectangular frame. The pattern through holes 34 are each circular in plan view. As shown in FIG. 5, in the first embodiment, the diameter of the substrate through hole 27 is equal to the diameter of the pattern through hole 34. In an example, the diameter of each of the substrate through hole 27 and the pattern through hole 34 is ½ of the width-wise dimension WA of the adhesion pattern 33. The diameters of the substrate through hole 27 and the pattern through hole 34 may be changed in any manner. The cap 70 is mounted on the adhesive 90. Portions of the adhesive 90 penetrate into the pattern through holes 34. Also, portions of the adhesive 90 penetrate into the substrate through holes 27. That is, as shown in FIG. 6, the adhesive 90 includes a surface adhesive portion 91 located on the adhesion pattern 33, a pattern adhesive portion 92 penetrating into the pattern through hole 34, and a substrate adhesive portion 93 penetrating into the substrate through hole 27.

The surface adhesive portion 91 is, for example, formed on the entire upper surface of the adhesion pattern 33. The surface adhesive portion 91 is in contact with the open-end surface 76 of the fourth side wall 74. As shown in FIG. 4, the surface adhesive portion 91 is in contact with the open-end surfaces 76 of the first side wall 71 and the second side wall 72. Although not shown in FIG. 4, the surface adhesive portion 91 is also in contact with the open-end surface 76 of the third side wall 73. As described above, the surface adhesive portion 91 bonds the adhesion pattern 33 and the cap 70.

As shown in FIG. 6, the pattern adhesive portion 92 fills the pattern through hole 34. In an example, the pattern adhesive portion 92 fills the entirety of the pattern through hole 34. Thus, the pattern adhesive portion 92 is in contact with the entire wall surface of the pattern through hole 34.

The substrate adhesive portion 93 penetrates into a portion of the substrate through hole 27 located close to the substrate front surface 21 in the Z-direction. The substrate adhesive portion 93 is separated from the substrate back surface 22 in the Z-direction. In an example, the substrate adhesive portion 93 is in contact with the entire wall surface of the substrate through hole 27 located at the end of the substrate through hole 27 located close to the substrate front surface 21 in the Z-direction. As described above, the adhesive 90 is in contact with the cap 70, the adhesion pattern 33, and the substrate 20. In other words, the substrate adhesive portion 93 is exposed to the outside of the semiconductor light emitting device 10 through the substrate through hole 27.

### Manufacturing Method of Semiconductor Light Emitting Device

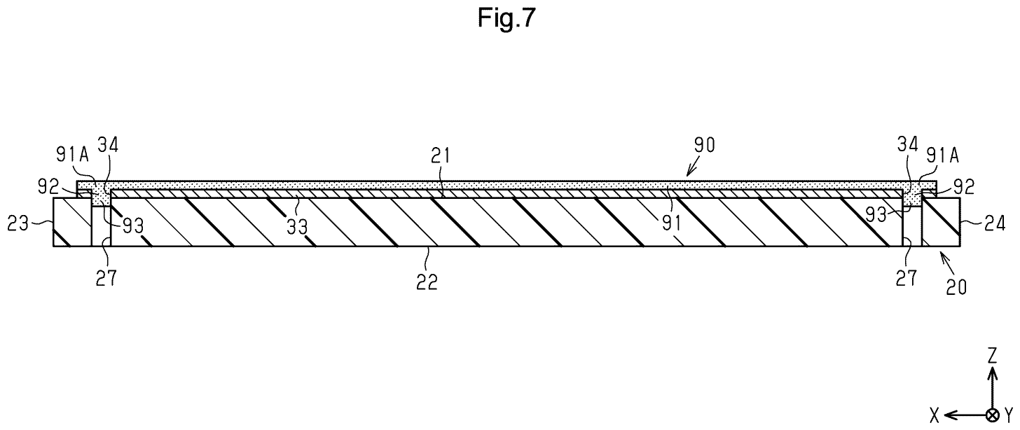

An example of a method for manufacturing the semiconductor light emitting device 10 will now be described with reference to FIGS. 7 to 10. FIGS. 7 to 10 are each a cross-sectional view showing a state in which the fourth side wall 74 of the cap 70 is bonded to the adhesion pattern 33. Although not shown in the drawings, the state in which the first to third side walls 71 to 73 of the cap 70 are bonded to the adhesion pattern 33 is the same as the state in which the fourth side wall 74 of the cap 70 is bonded to the adhesion pattern 33.

The method for manufacturing the semiconductor light emitting device 10 mainly includes a step of preparing the substrate 20, a step of mounting the submount substrate 80 on the substrate 20, a step of mounting the edge-emitting light emitting element 60 on the submount substrate 80, a step of forming the wires W, a step of applying the adhesive 90 to the adhesion pattern 33, a step of mounting the cap 70 on the adhesive 90 to accommodate the edge-emitting light emitting element 60, and a step of curing the adhesive 90.

In the step of preparing the substrate 20, the substrate 20 (refer to, for example, FIG. 7) including the substrate front surface 21 and the substrate back surface 22 opposite to the substrate front surface 21 is prepared. The front electrodes 30 and the adhesion pattern 33 are formed on the substrate front surface 21 of the substrate 20. The back electrodes 40 are formed on the substrate back surface 22. The adhesion pattern 33 is frame-shaped and surrounds the front electrodes 30. The adhesion pattern 33 has multiple (in the first embodiment, four) pattern through holes 34. The substrate 20 has multiple (in the first embodiment, four) substrate through holes 27. The substrate through holes 27 are separately connected to the pattern through holes 34. Although not shown in FIGS. 7 to 10, the multiple back electrodes 40 (refer to FIG. 3) are formed on the substrate back surface 22 of the substrate 20.

Next, in the step of mounting the submount substrate 80 on the substrate 20, which is not shown, a first conductive bonding material is applied to the element front electrode 31 among the front electrodes 30. The submount substrate 80 is mounted on the first conductive bonding material. That is, in this step, the submount substrate 80 is die-bonded to the element front electrode 31. The first conductive bonding material is a die bonding material and is, for example, solder paste or silver paste.

Next, in the step of mounting the edge-emitting light emitting element 60 on the submount substrate 80, which is not shown, a second conductive bonding material is applied to the front surface 81 of the submount substrate 80. The edge-emitting light emitting element 60 is mounted on the second conductive bonding material. That is, in this step, the edge-emitting light emitting element 60 is die-bonded to the submount substrate 80. The second conductive bonding material is a die bonding material and is, for example, solder paste or silver paste. The first conductive bonding material may be the same as or different from the second conductive bonding material. Thus, the edge-emitting light emitting element 60 is mounted on the substrate 20 inside the frame of the adhesion pattern 33. The method for manufacturing the semiconductor light emitting device 10 in the first embodiment includes a step of mounting the edge-emitting light emitting element 60 on the substrate 20 inside the frame of the adhesion pattern 33.

In the first embodiment, after the edge-emitting light emitting element 60 is mounted on the submount substrate 80, the first conductive bonding material and the second conductive bonding material are simultaneously cured. More specifically, the first conductive bonding material and the second conductive bonding material are heated and then cooled. This cures the first conductive bonding material and the second conductive bonding material. As a result, the first conductive bonding material bonds the element front electrode 31 and the submount substrate 80, and the second conductive bonding material bonds the submount substrate 80 and the edge-emitting light emitting element 60. Alternatively, the first conductive bonding material and the second conductive bonding material may be separately cured. In an example, in the step of mounting the submount substrate 80 on the substrate 20, the first conductive bonding material is cured to bond the element front electrode 31 and the submount substrate 80. Subsequently, in the step of mounting the edge-emitting light emitting element 60 on the submount substrate 80, the second conductive bonding material is cured to bond the submount substrate 80 and the edge-emitting light emitting element 60.

Next, in the step of forming the wires W, which is not shown, the wires W are formed to separately connect the element electrodes 63 of the edge-emitting light emitting element 60 and the front electrodes 30 using a wire bonder. Thus, the element electrodes 63 are separately electrically connected to the front electrodes 30.

Next, as shown in FIG. 7, in the step of applying the adhesive 90 to the adhesion pattern 33, for example, a dispenser is used to apply the adhesive 90 to the entire upper surface of the adhesion pattern 33. In the first embodiment, the adhesive 90 includes an ultraviolet/thermal dual-curing adhesive.

Portions of the adhesive 90 fill the pattern through holes 34 in the adhesion pattern 33. Portions of the adhesive 90 fill the substrate through holes 27 in the substrate 20. In the example shown in FIG. 7, the portions of the adhesive 90 filling the substrate through holes 27 fill only the end part of the substrate through holes 27 located close to the substrate front surface 21 in the Z-direction. That is, the adhesive 90 does not entirely fill the substrate through holes 27 in the Z-direction. Thus, in the step of applying the adhesive 90 to the adhesion pattern 33, the adhesive 90 is applied to the adhesion pattern 33 so as to penetrate into the pattern through holes 34. In the step of applying the adhesive 90 to the adhesion pattern 33, the adhesive 90 is applied to the adhesion pattern 33 so as to penetrate into the substrate through holes 27 through the pattern through holes 34.

As viewed from the substrate back surface 22, the adhesive 90 includes portions exposed from the substrate through holes 27. More specifically, the adhesive 90 includes the surface adhesive portion 91 applied to the adhesion pattern 33, the pattern adhesive portions 92 penetrating into the pattern through holes 34, and the substrate adhesive portions 93 penetrating into the substrate through holes 27. Of the adhesive 90, the pattern adhesive portions 92, the substrate adhesive portions 93, and parts (overlaps 91A) of the surface adhesive portion 91 that overlap the pattern adhesive portions 92 in plan view are exposed from the substrate through holes 27. In other words, the adhesive 90 exposed from the substrate through holes 27 includes the pattern adhesive portions 92, the substrate adhesive portions 93, and the overlaps 91A.

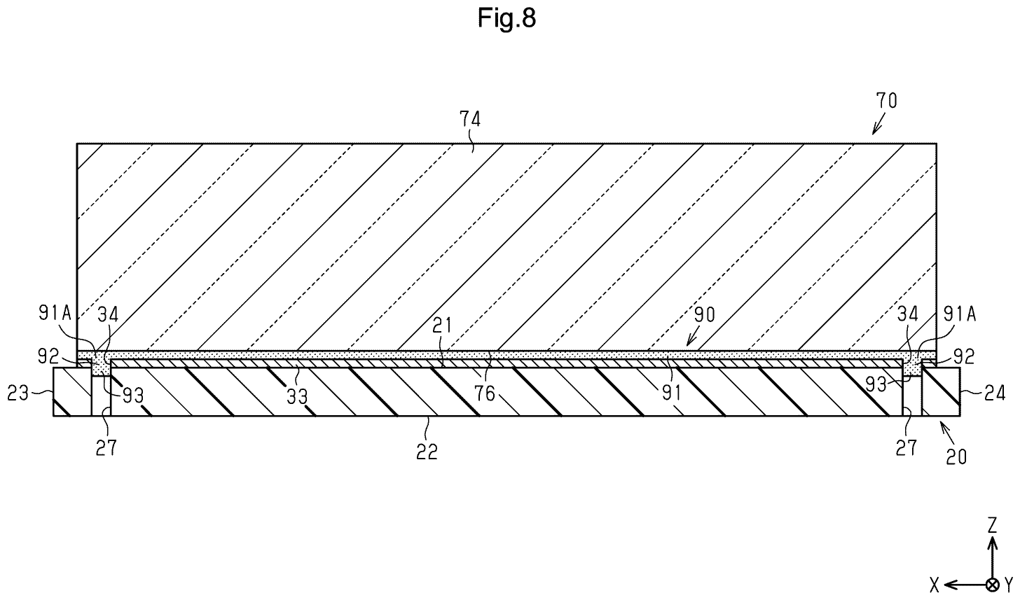

As shown in FIG. 8, in the step of mounting the cap 70 on the adhesive 90 to accommodate the edge-emitting light emitting element 60 (refer to FIG. 2), the first to fourth side walls 71 to 74 of the cap 70 are mounted on the adhesive 90. Consequently, for example, in the example shown in FIG. 8, the open-end surface 76 of the fourth side wall 74 is in contact with the adhesive 90. Also, although not shown in FIG. 8, the open-end surfaces 76 (refer to FIG. 4) of the first side wall 71 and the second side wall 72 are in contact with the adhesive 90. The open-end surface 76 of the third side wall 73 is also in contact with the adhesive 90. More specifically, the open-end surfaces 76 of the first to fourth side walls 71 to 74 of the cap 70 are entirely in contact with the surface adhesive portion 91 of the adhesive 90. The surface adhesive portion 91 is in contact with the entire upper surface of the adhesion pattern 33.

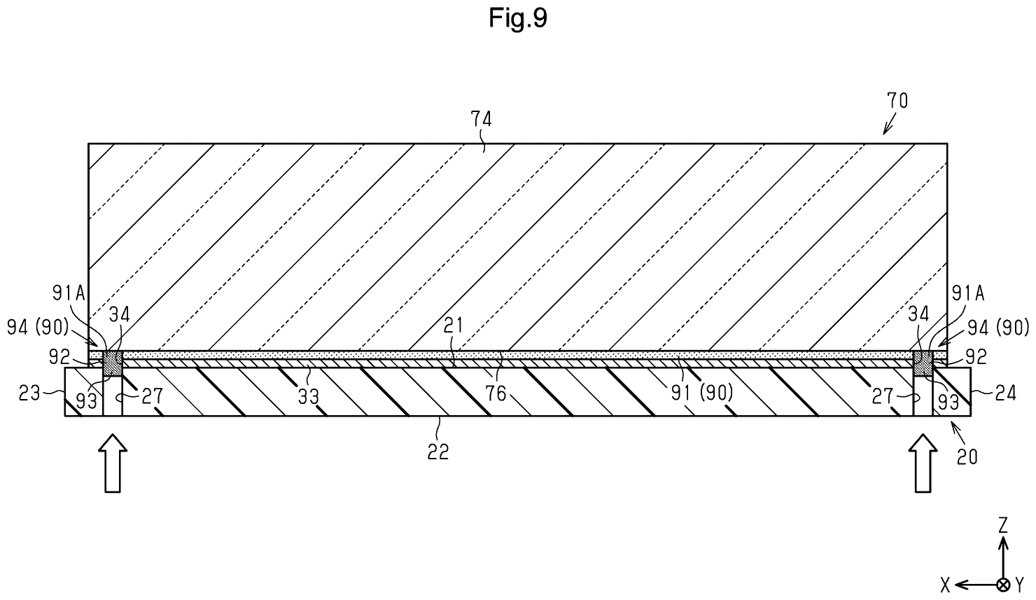

As shown in FIG. 9, the step of curing the adhesive 90 includes curing the adhesive 90 exposed from the substrate through holes 27 by irradiating the adhesive 90 exposed from the substrate through holes 27 with ultraviolet rays (indicated by white arrows). More specifically, an ultraviolet irradiation device (not shown) is used to irradiate the substrate back surface 22 with ultraviolet rays. In this case, the adhesive 90 exposed from the substrate through holes 27 is irradiated with ultraviolet rays. In an example, the portions of the adhesive 90 exposed from the substrate through holes 27 are simultaneously irradiated with ultraviolet rays. As a result, the portions of the adhesive 90 exposed from the substrate through holes 27 are simultaneously cured.

In FIG. 9 the dense dot regions indicate the portions of the adhesive 90 that have been cured by ultraviolet rays. Thus, in this step, a portion of the adhesive 90 is cured. The portion of the adhesive 90 that is cured, namely, a cured portion 94 includes the overlap 91A, the pattern adhesive portion 92, and the substrate adhesive portion 93. Thus, the cured portion 94 is formed by irradiating the adhesive 90 exposed from the substrate through hole 27 with ultraviolet rays. The cured portion 94 partially fixes the cap 70, the adhesion pattern 33, and the substrate 20. The step of curing the adhesive 90 exposed from the substrate through holes 27 may be referred to as a step of temporarily fixing the cap 70 to the adhesion pattern 33.

The pattern through holes 34 are formed in the four corners of the adhesion pattern 33 having the form of a rectangular frame in plan view. Thus, the cured portions 94 bond four corners of the first to fourth side walls 71 to 74 of the cap 70 and four corners of the adhesion pattern 33. In the step of temporarily fixing the cap 70 to the adhesion pattern 33, displacement and inclination of the cap 70 with respect to the adhesion pattern 33 are restricted.

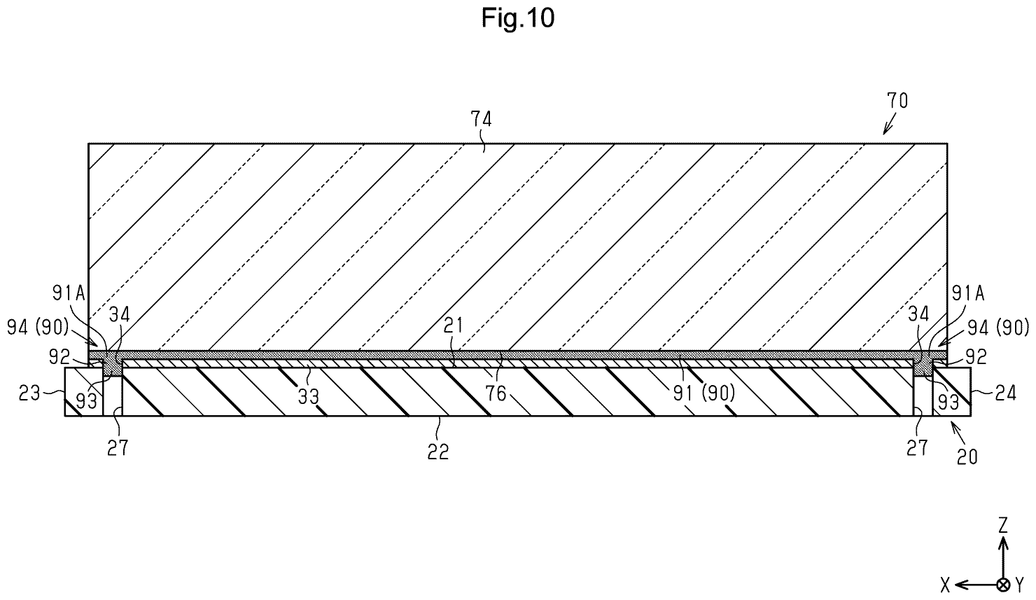

As shown in FIG. 10, the step of curing the adhesive 90 includes curing the entirety of the adhesive 90. In this step, the portion (the surface adhesive portion 91) of the adhesive 90 formed on the adhesion pattern 33 is cured.

In the first embodiment, in the step of curing the entirety of the adhesive 90, the adhesive 90 is thermally cured. In an example, the semiconductor light emitting device 10 is placed in a high-temperature oven (not shown) and is heated at a thermosetting temperature of the ultraviolet/thermal curing adhesive so that the adhesive 90 is entirely cured. As a result, the cap 70 is fixed to the adhesion pattern 33. The steps described above manufacture the semiconductor light emitting device 10.

### Operation

The operation of the semiconductor light emitting device 10 in accordance with the first embodiment will now be described. A structure of the adhesion pattern 33 that does not have the pattern through holes 34 is referred to as a “comparative adhesion pattern.”

Portions of the adhesive 90 penetrate into the pattern through holes 34 in the adhesion pattern 33. The area of contact of the adhesive 90 with the adhesion pattern 33 is increased as compared to a structure in which the adhesive 90 is applied to the upper surface of the comparative adhesion pattern. This increases the bonding strength between the adhesive 90 and the adhesion pattern 33, thereby limiting separation of the cap 70 from the substrate 20 (the adhesion pattern 33).

When the comparative adhesion pattern and the cap are bonded to each other by an adhesive, the cap 70 may be bonded to the comparative adhesion pattern in a state where the open-end surface 76 of the cap 70 is not parallel to the comparative adhesion pattern and is inclined with respect to a direction orthogonal to the Z-direction due to the curing of the adhesive.

In the method for manufacturing the semiconductor light emitting device 10 in the first embodiment, the adhesive 90 exposed from the substrate through holes 27 is irradiated with ultraviolet rays and is cured. As a result, the cured portion 94 is formed in the adhesive 90 to connect the adhesion pattern 33 and the cap 70 so that the adhesion pattern 33 is temporarily fixed to the cap 70. When the adhesion pattern 33 is temporarily fixed to the cap 70, the entirety of the adhesive 90 is cured. The temporary fixing of the adhesion pattern 33 to the cap 70 limits inclination of the cap 70 with respect to the adhesion pattern 33 and displacement of the cap 70 in the width-wise direction of the adhesion pattern 33 caused by shrinkage of the adhesive 90 due to the curing of the entirety of the adhesive 90.

### Advantages

The semiconductor light emitting device 10 of the first embodiment has the advantages described below.
(1-1) The semiconductor light emitting device 10 includes the substrate 20, the edge-emitting light emitting element 60 mounted on the substrate 20, the cap 70 accommodating the edge-emitting light emitting element 60, and the adhesive 90 bonding the cap 70 and the substrate 20. As viewed in the Z-direction, or the thickness-wise direction of the substrate 20, the substrate 20 has the substrate through holes 27 overlapping the adhesive 90. The semiconductor light emitting device 10 includes the adhesion pattern 33 formed on the substrate 20 to surround the edge-emitting light emitting element 60 as viewed in the Z-direction. The adhesive 90 is disposed on the adhesion pattern 33 so as to bond the adhesion pattern 33 and the cap 70. The pattern through hole 34 is formed in the adhesion pattern 33 and is connected to the substrate through hole 27. A portion of the adhesive 90 penetrates into the pattern through hole 34.

In this structure, the portion of the adhesive 90 penetrating into the pattern through hole 34 increases the area in which the adhesive 90 is bonded to the adhesion pattern 33. This limits separation of the adhesive 90 from the adhesion pattern 33, thereby increasing the bonding strength between the adhesion pattern 33 and the cap 70 with the adhesive 90.
(1-2) Multiple substrate through holes 27 and multiple pattern through holes 34 are arranged.

In this structure, the adhesive 90 penetrates into the multiple pattern through holes 34, thereby further increasing the area in which the adhesive 90 is bonded to the adhesion pattern 33. This increases the bonding strength between the adhesion pattern 33 and the cap 70 with the adhesive 90.
(1-3) The adhesive 90 penetrates into the substrate through hole 27.

In this structure, the adhesive 90 is in contact with the wall of the pattern through hole 34 and the wall of the substrate through hole 27. Thus, the adhesive 90 is bonded to the substrate 20 in addition to the adhesion pattern 33. This further limits separation of the adhesive 90 from the adhesion pattern 33, thereby increasing the bonding strength between the adhesion pattern 33 and the cap 70 with the adhesive 90.
(1-4) As viewed in the Z-direction, the adhesion pattern 33 is rectangular-frame-shaped. The pattern through holes 34 are arranged at the four corners of the adhesion pattern 33.

This structure limits unevenness of the bonding strength between the adhesion pattern 33 and the cap 70 with the adhesive 90. This avoids a situation in which the open-end surface 76 of the cap 70 is not parallel to the adhesion pattern 33 and is inclined with respect to a direction orthogonal to the Z-direction.
(1-5) As viewed in the Z-direction, the adhesion pattern 33 is rectangular-frame-shaped and extends in the longitudinal direction and the lateral direction. The pattern through hole 34 is further arranged at the center in the longitudinal direction of the adhesion pattern 33.

With this structure, the area in which the adhesive 90 is bonded to the adhesion pattern 33 is further increased. Accordingly, the bonding strength between the adhesion pattern 33 and the cap 70 with the adhesive 90 is increased.
(1-6) The method for manufacturing the semiconductor light emitting device 10 includes a step of preparing the substrate 20 including the substrate front surface 21 and the substrate back surface 22 that are located at opposite sides of the substrate 20, the frame-shaped adhesion pattern 33 formed on the substrate front surface 21, the pattern through hole 34 formed in the adhesion pattern 33, and the substrate through hole 27 connected to the pattern through hole 34. The method further includes a step of mounting the edge-emitting light emitting element 60 on the substrate 20 inside the frame of the adhesion pattern 33, a step of applying the adhesive 90 to the adhesion pattern 33, and a step of mounting the cap 70 on the adhesive 90 to accommodate the edge-emitting light emitting element 60. In the step of applying the adhesive 90 to the adhesion pattern 33, the adhesive 90 is applied to the adhesion pattern 33 so as to penetrate into the pattern through hole 34.

In this structure, the adhesive 90 is applied so as to penetrate into the pattern through hole 34 so that the area in which the adhesive 90 is bonded to the adhesion pattern 33 is increased. This limits separation of the adhesive 90 from the adhesion pattern 33, thereby increasing the bonding strength between the adhesion pattern 33 and the cap 70 with the adhesive 90.
(1-7) The method for manufacturing the semiconductor light emitting device 10 further includes a step of curing the adhesive 90 exposed from the substrate through hole 27 by irradiating the adhesive 90 exposed from the substrate through hole 27 with an ultraviolet ray, and a step of curing the entirety of the adhesive 90.

In this structure, the ultraviolet irradiation cures the adhesive 90 exposed from the substrate through holes 27. Thus, the cap 70 is partially bonded to the adhesion pattern 33. In the step of curing the entirety of the adhesive 90, a situation in which the open-end surface 76 of the cap 70 is not parallel to the adhesion pattern 33 and is inclined with respect to a direction orthogonal to the Z-direction due to the curing of the adhesive 90 is limited.
(1-8) Multiple substrate through holes 27 are arranged. In the step of curing the adhesive 90 exposed from the substrate through holes 27, the portions of the adhesive 90 exposed from the substrate through holes 27 are simultaneously irradiated with ultraviolet rays.

In this structure, the portions of the adhesive 90 exposed from the substrate through holes 27 are simultaneously cured. This simplifies the step as compared to when the portions of the adhesive 90 exposed from the substrate through holes 27 are individually cured.
(1-9) In the step of applying the adhesive 90 to the adhesion pattern 33, the adhesive 90 is applied to the adhesion pattern 33 so as to penetrate into the substrate through hole 27 through the pattern through hole 34.

In this structure, the adhesive 90 is applied to the adhesion pattern 33 so as to penetrate into the pattern through hole 34 and the substrate through hole 27. Thus, the adhesive 90 is bonded to the substrate 20 in addition to the adhesion pattern 33. This further limits separation of the adhesive 90 from the adhesion pattern 33, thereby increasing the bonding strength between the adhesion pattern 33 and the cap 70 with the adhesive 90.
(1-10) The width-wise dimension WB of the first to fourth side walls 71 to 74 of the cap 70 is equal to the width-wise dimension WA of the adhesion pattern 33.

In this structure, displacement of the cap 70 from the adhesion pattern 33 in the width-wise direction of the adhesion pattern 33 due to the curing of the adhesive 90 is limited. In addition, a situation in which the open-end surface 76 of the cap 70 is not parallel to the adhesion pattern 33 and is inclined with respect to a direction orthogonal to the Z-direction is avoided.

### Second Embodiment

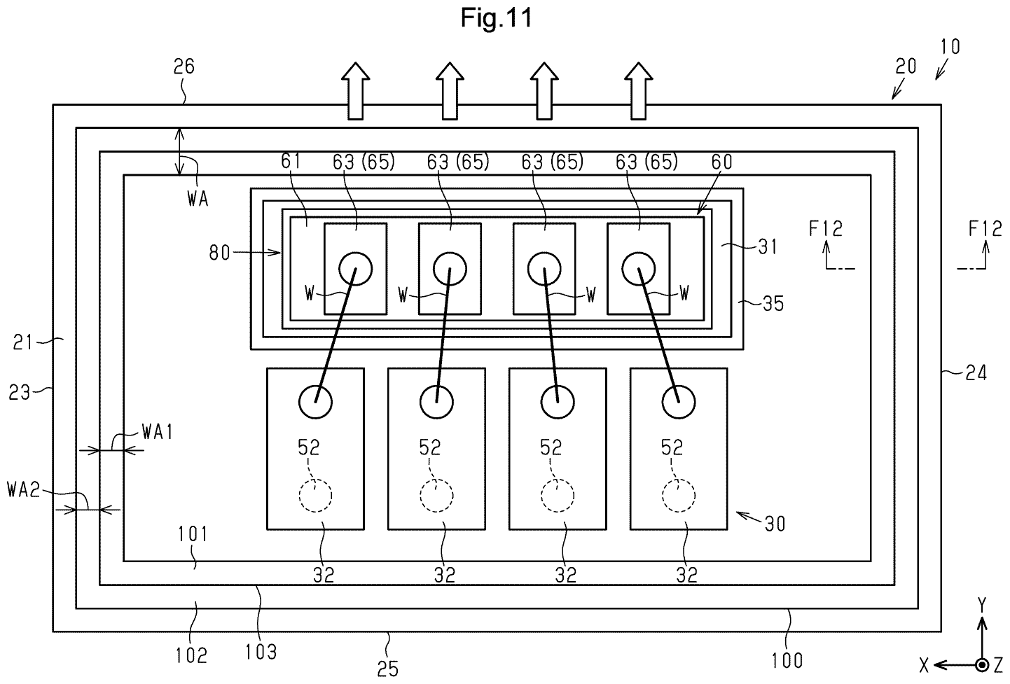

A second embodiment of a semiconductor light emitting device 10 will now be described with reference to FIGS. 11 to 16. The semiconductor light emitting device 10 of the second embodiment differs from the semiconductor light emitting device 10 of the first embodiment in the structure of an adhesion pattern 100 and a step of bonding the adhesion pattern 33 and the cap 70 with the adhesive 90. In the following description, the differences from the first embodiment will be described in detail. The same reference characters are given to those components that are the same as the corresponding components of the first embodiment. Such components will not be described in detail.

### Bonding Structure of Cap and Adhesion Pattern

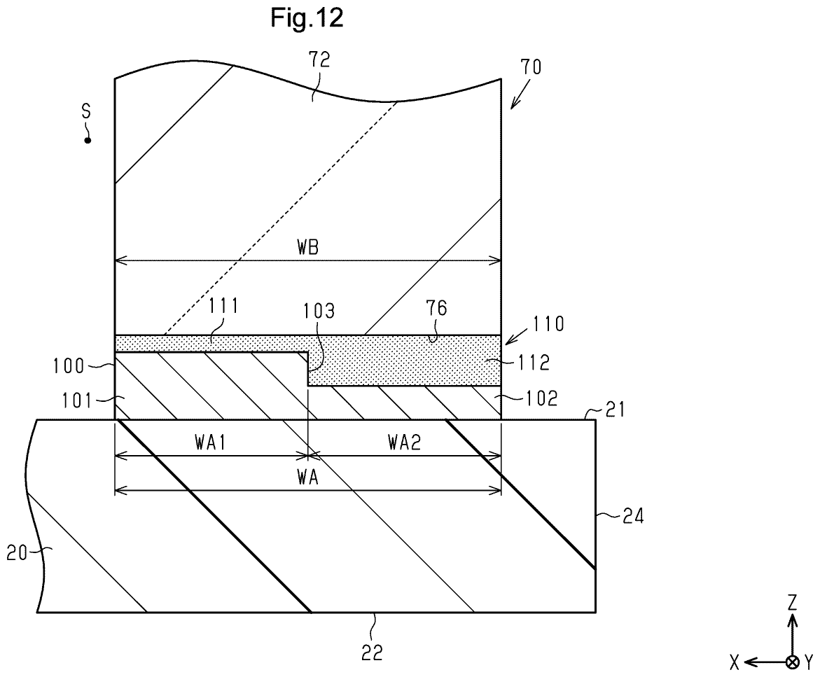

FIG. 11 shows an internal structure of the semiconductor light emitting device 10 in the second embodiment. In FIG. 11, the cap 70 is not shown to facilitate understanding of the adhesion pattern 33. FIG. 12 is a cross-sectional view taken along line F12-F12 in FIG. 11 showing the bonding state of the second side wall 72 of the cap 70 and the adhesion pattern 33.

As shown in FIG. 11, the adhesion pattern 100 has the form of a rectangular frame and surrounds the front electrodes 30 in plan view in the same manner as the adhesion pattern 33 of the first embodiment. As shown in FIG. 12, the adhesion pattern 100 includes a high step 101 located in an inner part of the adhesion pattern 100 and a low step 102 located in an outer part of the adhesion pattern 100 and being smaller in thickness than the high step 101. The adhesion pattern 100 includes a step wall 103 located between the low step 102 and the high step 101.

The adhesion pattern 100 is arranged on a peripheral portion of the substrate front surface 21. The adhesion pattern 100 has sides respectively arranged adjacent to the first to fourth substrate side surfaces 23 to 26 in plan view. The adhesion pattern 100 has a first side arranged adjacent to the first substrate side surface 23 and extending along the first substrate side surface 23 in plan view. The adhesion pattern 100 has a second side arranged adjacent to the second substrate side surface 24 and extending along the second substrate side surface 24 in plan view. The adhesion pattern 100 has a third side arranged adjacent to the third substrate side surface 25 and extending along the third substrate side surface 25 in plan view. The adhesion pattern 100 has a fourth side arranged adjacent to the fourth substrate side surface 26 and extending along the fourth substrate side surface 26 in plan view.

The inner part of the adhesion pattern 100 is located at the side of the sealed space S (refer to FIG. 12) defined by the cap 70 and the substrate 20. That is, the high step 101 is formed in a part of the adhesion pattern 100 at the side of the sealed space S. In other words, the inner part of the adhesion pattern 100 is located toward the center of the substrate front surface 21 in the width-wise direction of the adhesion pattern 100. That is, the high step 101 is formed on a part of the substrate front surface 21 located toward the center of the substrate front surface 21 in the width-wise direction of the adhesion pattern 100. In other words, the inner part of the adhesion pattern 100 is located close to the front electrodes 30 and the edge-emitting light emitting element 60 in the width-wise direction of the adhesion pattern 100. The width-wise direction of the adhesion pattern 100 refers to a direction orthogonal to the direction in which the adhesion pattern 100 extends in plan view.

The outer part of the adhesion pattern 100 is located at the side opposite to the sealed space S. That is, the low step 102 is formed in a part of the adhesion pattern 100 at the side opposite to the sealed space S. In other words, the outer part of the adhesion pattern 100 is located toward the end of the substrate front surface 21 in the width-wise direction of the adhesion pattern 100. That is, the low step 102 is formed on a part of the substrate front surface 21 located toward the end of the substrate front surface 21 in the width-wise direction of the adhesion pattern 100. The outer part of the adhesion pattern 100 is located toward the first to fourth substrate side surfaces 23 to 26 of the substrate 20, each corresponding to one side of the adhesion pattern 100, in the width-wise direction of the adhesion pattern 100. That is, the low step 102 is formed on a part of the adhesion pattern 100 located toward the first to fourth substrate side surfaces 23 to 26, each corresponding to one side of the adhesion pattern 100, in the width-wise direction of the adhesion pattern 100. In other words, the inner part of the adhesion pattern 100 is located away from the front electrodes 30 and the edge-emitting light emitting element 60 in the width-wise direction of the adhesion pattern 100.

In the second embodiment, the step wall 103 is located at the center in the width-wise direction of the adhesion pattern 100. Thus, the high step 101 includes a part of the adhesion pattern 100 located inward from the center in the width-wise direction of the adhesion pattern 100. The low step 102 includes a part of the adhesion pattern 100 outward from the center in the width-wise direction of the adhesion pattern 100. Thus, in the second embodiment, the width-wise dimension WA1 of the high step 101 is equal to the width-wise dimension WA2 of the low step 102. In the second embodiment, the width-wise dimension WA of the adhesion pattern 100 is equal to the width-wise dimension WB of each of the first to fourth side walls 71 to 74 of the cap 70 in the same manner as the adhesion pattern 33 of the first embodiment.

As shown in FIG. 11, the step wall 103 extends along the entire perimeter of the adhesion pattern 100. Accordingly, the high step 101 and the low step 102 each extend along the entire perimeter of the adhesion pattern 100. As shown in FIG. 12, in the second embodiment, the thickness of the low step 102 is ½ of the thickness of the high step 101. The thickness of each of the high step 101 and the low step 102 may be changed in any manner. The thickness of the low step 102 may be greater than ½ of the thickness of the high step 101 or may be less than the ½ of the thickness of the high step 101.

In the second embodiment, the upper surface of the low step 102 has a greater surface roughness than the upper surface of the high step 101. In an example, the entire upper surface of the low step 102 has a greater surface roughness than the upper surface of the high step 101. In an example, the low step 102 is formed by laser irradiation or etching. As a result, the entire upper surface of the low step 102 has a greater surface roughness than the upper surface of the high step 101.

In addition, when laser irradiation or etching is performed to form the low step 102, a side surface defining the step wall 103 is also formed. Thus, the side surface of the step wall 103 has a greater surface roughness than the upper surface of the high step 101. In an example, the entire side surface of the step wall 103 has a greater surface roughness than the upper surface of the high step 101.

A roughening process may be performed on the upper surface of the low step 102 to roughen the upper surface of the low step 102. An example of the roughening process may be a brown process that form fine irregularities on the upper surface of the low step 102. The region of the upper surface of the low step 102 that is roughened may be changed in any manner. In an example, a portion of the upper surface of the low step 102 has a greater surface roughness than the upper surface of the high step 101.

In the second embodiment, an adhesive 110 that bonds the adhesion pattern 100 and the cap 70 is a thermosetting adhesive.

Since the open-end surface 76 of the second side wall 72 of the cap 70 is flat and is orthogonal to the Z-direction, when the adhesive 110 is applied between the open-end surface 76 and the adhesion pattern 100, the adhesive 110 includes a thin adhesion layer 111 located on the inner part of the adhesion pattern 100 and a thick adhesion layer 112 located on the outer part of the adhesion pattern 100 and being greater in thickness than the thin adhesion layer 111. In the same manner, although not shown in FIG. 12, the adhesive 110 applied between the adhesion pattern 100 and each of the first side wall 71, the third side wall 73, and the fourth side wall 74 includes the thin adhesion layer 111 and the thick adhesion layer 112. Thus, the thin adhesion layer 111 and the thick adhesion layer 112 are in contact with the open-end surfaces 76 of the first to fourth side walls 71 to 74 of the cap 70.

The thin adhesion layer 111 is arranged on the high step 101 of the adhesion pattern 100. That is, the thin adhesion layer 111 is arranged between the high step 101 and the cap 70. More specifically, the thin adhesion layer 111 is arranged between the high step 101 and the first to fourth side walls 71 to 74 of the cap 70 in the Z-direction. Thus, the thin adhesion layer 111 is the portion of the adhesive 110 that bonds the high step 101 and the first to fourth side walls 71 to 74 of the cap 70.

The thin adhesion layer 111 is formed on the entire upper surface of the high step 101. The thin adhesion layer 111 is formed on the entire inner part of the open-end surfaces 76 of the first to fourth side walls 71 to 74. The inner part of the open-end surfaces 76 of the first to fourth side walls 71 to 74 is opposed to the high step 101 in the Z-direction. The inner part of the open-end surfaces 76 of the first to fourth side walls 71 to 74 is located at the side of the sealed space S defined by the cap 70 and the substrate 20. In other words, the inner part of the open-end surface 76 is locate toward the center of the substrate front surface 21 in the width-wise direction of the open-end surface 76.

The thick adhesion layer 112 is arranged on the low step 102 of the adhesion pattern 100. That is, the thick adhesion layer 112 is arranged between the low step 102 and the cap 70. More specifically, the thick adhesion layer 112 is arranged between the low step 102 and the first to fourth side walls 71 to 74 of the cap 70 in the Z-direction. Thus, the thick adhesion layer 112 is the portion of the adhesive 110 that bonds the low step 102 and the first to fourth side walls 71 to 74 of the cap 70.

In the second embodiment, the open-end surfaces 76 of the first to fourth side walls 71 to 74 of the cap 70 are flat and are orthogonal to the Z-direction, and the thickness of the low step 102 is ½ of the thickness of the high step 101. Therefore, the thickness of the thick adhesion layer 112 is twice the thickness of the thin adhesion layer 111. The relationship between the thickness of the thin adhesion layer 111 and the thickness of the thick adhesion layer 112 may be changed in any manner in accordance with the shapes of the open-end surfaces 76 of the first to fourth side walls 71 to 74 of the cap 70 and the high step 101 and the low step 102 of the adhesion pattern 100.

The thick adhesion layer 112 is formed on the entire upper surface of the low step 102. The thick adhesion layer 112 is formed on the entire outer part of the open-end surfaces 76 of the first to fourth side walls 71 to 74. The outer part of the open-end surfaces 76 of the first to fourth side walls 71 to 74 is opposed to the low step 102 in the Z-direction. The outer part of the open-end surfaces 76 of the first to fourth side walls 71 to 74 is located at the side opposite to the sealed space S. In other words, the outer part of the open-end surface 76 is located toward the end of the substrate front surface 21 in the width-wise direction of the open-end surface 76.

As shown in FIG. 12, the adhesive 110 is in contact with the step wall 103. In an example, the adhesive 110 is in contact with the step wall 103 along the entire perimeter of the step wall 103. In other words, the thick adhesion layer 112 is in contact with the step wall 103.

### Manufacturing Method of Semiconductor Light Emitting Device

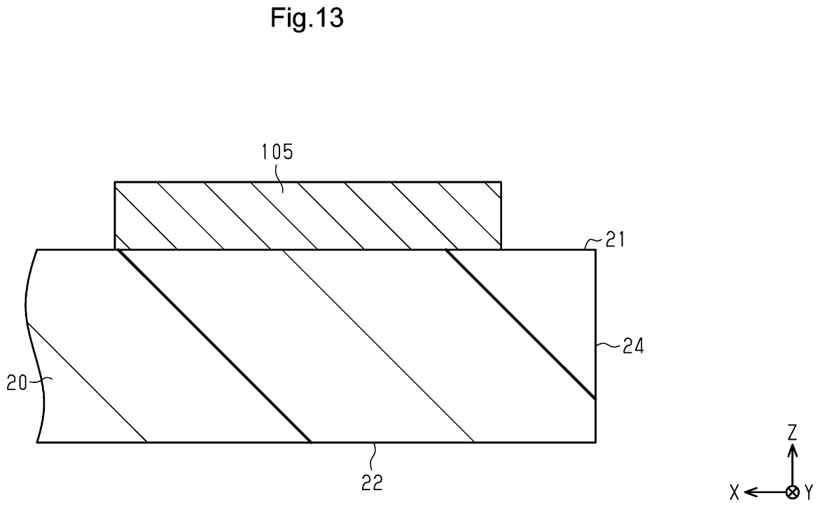

An example of a method for manufacturing the semiconductor light emitting device 10 in the second embodiment will now be described with reference to FIGS. 13 to 16. The method for manufacturing the semiconductor light emitting device 10 of the second embodiment differs from the first embodiment mainly in a step of forming the adhesion pattern 100 on the substrate 20, a step of applying the adhesive 110 to the adhesion pattern 100, and a step of curing the adhesive 110 to bond the adhesion pattern 100 and the cap 70. Differences from the method for manufacturing the semiconductor light emitting device 10 of the first embodiment will be described in detail.

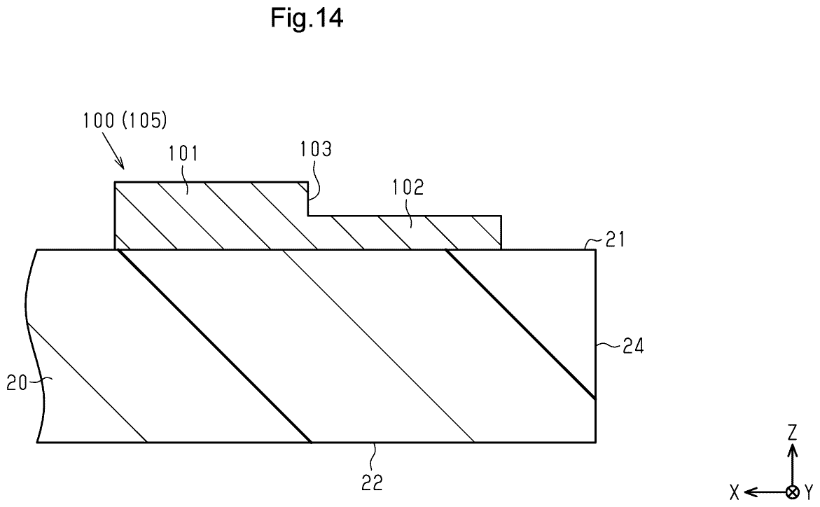

As shown in FIGS. 13 and 14, the method for manufacturing the semiconductor light emitting device 10 includes a step of forming the adhesion pattern 100 on the substrate 20. This step is included in, for example, the step of preparing the substrate 20. The adhesion pattern 100 includes the high step 101 located in the inner part of the adhesion pattern 100 and the low step 102 located in the outer part of the adhesion pattern 100 and being smaller in thickness than the high step 101.

In an example, the step of forming the adhesion pattern 100 includes a step of forming a frame-shaped pattern layer 105 having a uniform thickness as shown in FIG. 13. The pattern layer 105 is, for example, formed from a copper foil to form the adhesion pattern 100. The pattern layer 105 is not limited to Cu and may include at least one of Al, Ni, Pd, Ag, and Au. The thickness of the pattern layer 105 is, for example, equal to the thickness of the high step 101 of the adhesion pattern 100 shown in FIG. 10.

In an example, the step of forming the pattern layer 105 is performed simultaneously with a step of forming the front electrodes 30. That is, the front electrodes 30 and the pattern layer 105 are formed in the same step. The pattern layer 105 has the form of a rectangular frame surrounding the front electrodes 30 in plan view.

The step of forming the adhesion pattern 100 includes a step of forming the adhesion pattern 100 by reducing a thickness of the outer part of the pattern layer 105 to be smaller than a thickness of the inner part of the pattern layer 105 as shown in FIG. 14. In an example, in the step of forming the adhesion pattern 100, the high step 101 and the low step 102 are formed by thinning the outer part of the pattern layer 105 using laser irradiation or etching. The thickness of the outer part of the pattern layer 105, which is smaller than the thickness of the inner part of the pattern layer 105, is, for example, equal to the thickness of the low step 102 of the adhesion pattern 100 shown in FIG. 12. As described above, the adhesion pattern 100 includes the high step 101, the low step 102, and the step wall 103.

The outer part of the pattern layer 105 is located toward the end of the substrate 20 in the width-wise direction of the pattern layer 105. In other words, the outer part of the pattern layer 105 is located away from the front electrodes 30 and the edge-emitting light emitting element 60 in the width-wise direction of the pattern layer 105. The inner part of the pattern layer 105 is located toward the center of the substrate 20 in the width-wise direction of the pattern layer 105. In other words, the inner part of the pattern layer 105 is located close to the front electrodes 30 and the edge-emitting light emitting element 60 in the width-wise direction of the pattern layer 105. The outer part of the pattern layer 105 corresponds to the outer part of the adhesion pattern 100. The inner part of the pattern layer 105 corresponds to the inner part of the adhesion pattern 100.

The low step 102 is formed by laser irradiation or etching. Thus, the upper surface of the low step 102 has a greater surface roughness than the upper surface of the high step 101. The step wall 103 is also formed by laser irradiation or etching. Thus, the side surface of the step wall 103 has a greater surface roughness than the upper surface of the high step 101.

As described above, subsequent to the step of preparing the substrate 20 on which the adhesion pattern 100 is formed, in the same manner as the first embodiment, the step of mounting the submount substrate 80 on the substrate 20 (on the element front electrode 31), the step of mounting the edge-emitting light emitting element 60 on the submount substrate 80, and the step of forming the wires W are performed.

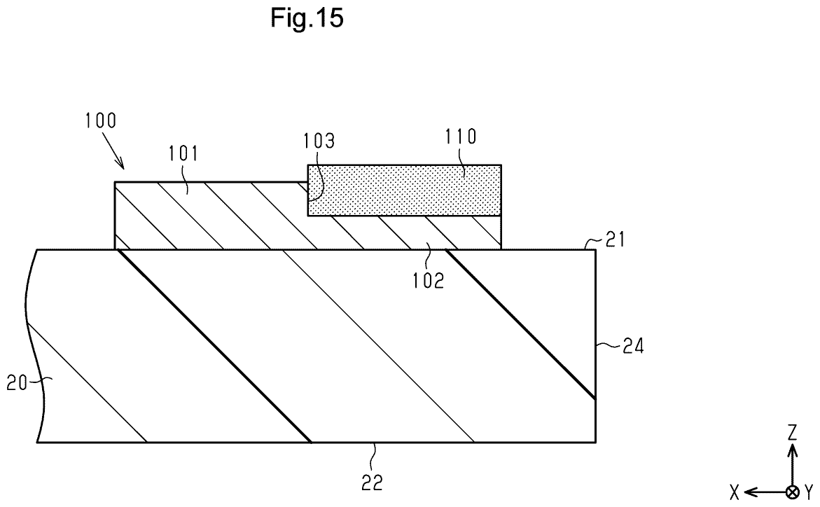

As shown in FIG. 15, a step of bonding the adhesion pattern 33 and the cap 70 with the adhesive 110 includes a step of applying the adhesive 110 to the adhesion pattern 100. For example, a dispenser is used to apply the adhesive 110 to the low step 102 without applying the adhesive 110 to the high step 101. More specifically, the adhesive 110 is applied to the low step 102 along the entire perimeter of the low step 102. The amount of the adhesive 110 is set so that the adhesive 110 is located higher than the upper surface of the high step 101. In an example, the adhesive 110 is in contact with the step wall 103 along the entire perimeter of the step wall 103. The step of forming the adhesion pattern 100 on the substrate 20 is performed prior to the step of applying the adhesive 110 to the adhesion pattern 100. In the second embodiment, the adhesive 110 is a thermosetting adhesive.

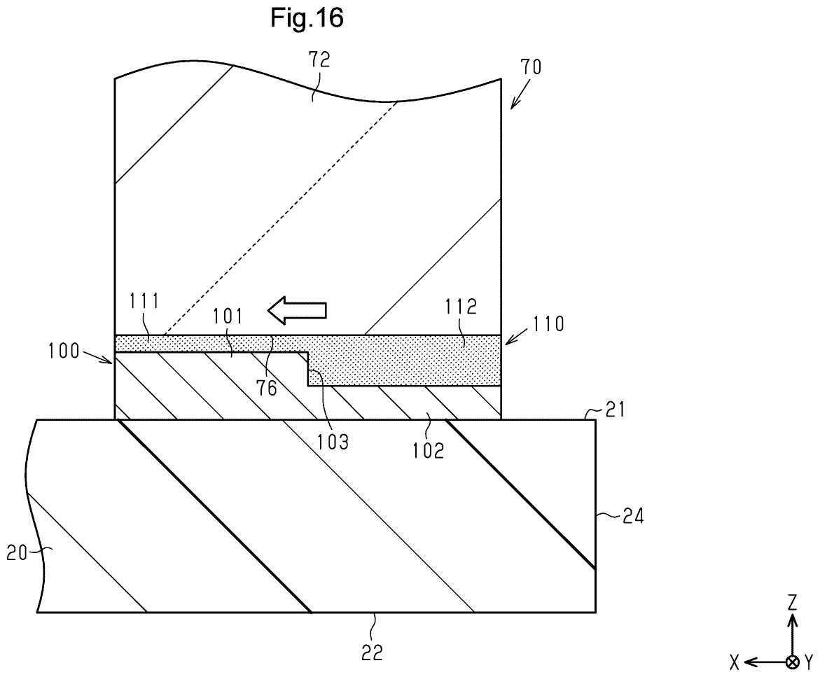

As shown in FIG. 16, in the step of mounting the cap 70 on the adhesive 110 to accommodate the edge-emitting light emitting element 60, the adhesive 110 is formed between the cap 70 and the adhesion pattern 100 to include the thin adhesion layer 111, which is located on the inner part of the adhesion pattern 100, and the thick adhesion layer 112, which is located on the outer part of the adhesion pattern 100 and is greater in thickness than the thin adhesion layer 111. More specifically, when the cap 70 is mounted on the adhesive 110, the cap 70 pushes the adhesive 110 toward the substrate front surface 21. This causes the adhesive 110 to be pushed out to the inner part of the adhesion pattern 100. Thus, the adhesive 110 is moved to the upper surface of the high step 101 of the adhesion pattern 100. As a result, the thin adhesion layer 111 is formed. The adhesive 110 that is applied to the upper surface of the low step 102 of the adhesion pattern 100 forms the thick adhesion layer 112. As described above, in the step of mounting the cap 70 on the adhesive 110 to accommodate the edge-emitting light emitting element 60, the adhesive 110 applied to the low step 102 is moved by the cap 70 to the high step 101 to form the thin adhesion layer 111.

The step of curing the adhesive 110 to bond the adhesion pattern 33 and the cap 70 includes a step of thermally curing the adhesive 110. In an example, the semiconductor light emitting device 10 is placed in a high-temperature oven (not shown) and is heated at a thermosetting temperature of a thermal curing adhesive so that the adhesive 110 is entirely cured. As a result, the cap 70 is bonded to the adhesion pattern 100. The steps described above manufacture the semiconductor light emitting device 10.

### Operation

The operation of the second embodiment will now be described. A structure of the adhesion pattern 100 that does not have the low step 102 and the step wall 103 is referred to as a “comparative adhesion pattern.”

When an adhesive is cured to bond the cap 70 to the comparative adhesion pattern and produces gas, the gas may be trapped in the adhesive. This may form a void that separates the adhesive from at least one of the open-end surface 76 of the cap 70 and the upper surface of the comparative adhesion pattern. Consequently, the bonding strength between the comparative adhesion pattern and the cap 70 with the adhesive is decreased. This may result in separation of the cap 70 from the comparative adhesion pattern.

In the second embodiment, the low step 102 is formed in the outer part of the adhesion pattern 100. Therefore, in the adhesive 110 formed on the adhesion pattern 100, the thick adhesion layer 112 is formed outward from the thin adhesion layer 111. With this structure, gas produced from the adhesive 110 moves from the thin adhesion layer 111 to the thick adhesion layer 112 and then is readily released from the thick adhesion layer 112 to the outside of the adhesive 110. Thus, the presence of gas in the adhesive 110 is limited, and a void is less likely to be formed between the adhesion pattern 100 and the open-end surface 76 of the cap 70 in the Z-direction. In other words, the adhesive 110 fills the space between the adhesion pattern 100 and the open-end surface 76 of the cap 70 in the Z-direction with no void. The area of the adhesive 110 that bonds the adhesion pattern 100 and the open-end surface 76 of the cap 70 is larger than the area of the adhesive in which the comparative adhesion pattern is bonded to the cap 70 with the adhesive. This increases the bonding strength between the adhesion pattern 100 and the cap 70 with the adhesive 110, thereby limiting separation of the cap 70 from the adhesion pattern 100.

### Advantages

The semiconductor light emitting device 10 of the second embodiment has the advantages described below.
(2-1) The semiconductor light emitting device 10 includes the substrate 20, the edge-emitting light emitting element 60 mounted on the substrate 20, the cap 70 accommodating the edge-emitting light emitting element 60, the frame-shaped adhesion pattern 100 arranged on the substrate 20 to surround the edge-emitting light emitting element 60 as viewed in the Z-direction, that is, the thickness-wise direction of the substrate 20, and the adhesive 110 bonding the cap 70 and the adhesion pattern 100. The adhesive 110 includes the thin adhesion layer 111, which is located on the inner part of the adhesion pattern 100, and the thick adhesion layer 112, which is located on the outer part of the adhesion pattern 100 and is greater in thickness than the thin adhesion layer 111.

In this structure, gas produced from the adhesive 110 is readily released from the thick adhesion layer 112 to the outside of the adhesive 110. Thus, the adhesive 110 fills the space between the adhesion pattern 100 and the cap 70 in the Z-direction with no void. As a result, the area in which the adhesion pattern 100 bonds the cap 70 with the adhesive 110 is increased. This increases the bonding strength between the adhesion pattern 100 and the cap 70 with the adhesive 110.
(2-2) The adhesion pattern 100 includes the high step 101 located in the inner part of the adhesion pattern 100 and the low step 102 located in the outer part of the adhesion pattern 100 and being smaller in thickness than the high step 101. The thin adhesion layer 111 is arranged between the high step 101 and the cap 70. The thick adhesion layer 112 is arranged between the low step 102 and the cap 70.

In this structure, since the high step 101 and the low step 102 are formed in the adhesion pattern 100, the thin adhesion layer 111 and the thick adhesion layer 112 are readily formed in the adhesive 110.
(2-3) The adhesion pattern 100 includes the step wall 103 located between the low step 102 and the high step 101. The adhesive 110 is in contact with the step wall 103.

In this structure, since the adhesive 110 is in contact with the step wall 103, the area in which the adhesive 110 is bonded to the adhesion pattern 100 is increased. This limits separation of the adhesive 110 from the adhesion pattern 100. Accordingly, the bonding strength between the adhesion pattern 100 and the cap 70 with the adhesive 110 is increased. In addition, for example, when external force is applied to the cap 70 in the width-wise direction of the adhesion pattern 100, the adhesive 110 that is in contact with the step wall 103 restricts movement of the cap 70 in the width-wise direction of the adhesion pattern 100.
(2-4) The low step 102 extends along the entire perimeter of the adhesion pattern 100.

With this structure, the area in which the adhesive 110 is bonded to the adhesion pattern 100 is increased. This increases the bonding strength between the adhesion pattern 100 and the cap 70 with the adhesive 110.
(2-5) The upper surface of the low step 102 has a greater surface roughness than the upper surface of the high step 101.

With this structure, the thick adhesion layer 112 of the adhesive 110 has the anchor effect between the upper surface of the low step 102 and the cap 70 to increase the bonding strength between the adhesion pattern 100 and the cap 70.
(2-6) The cap 70 is box-shaped and is open toward the substrate 20. The cap 70 includes the frame-shaped first to fourth side walls 71 to 74 surrounding the edge-emitting light emitting element 60 in plan view. The thin adhesion layer 111 and the thick adhesion layer 112 of the adhesive 110 are both in contact with the open-end surfaces 76 of the first to fourth side walls 71 to 74.

With this structure, the area of the adhesive 110 that bonds the adhesion pattern 100 and the cap 70 is increased. This increases the bonding strength between the adhesion pattern 100 and the cap 70 with the adhesive 110.
(2-7) The method for manufacturing the semiconductor light emitting device 10 includes the step of mounting the edge-emitting light emitting element 60 on the substrate 20, the step of applying the adhesive 110 to the adhesion pattern 100 arranged on the substrate 20 and surrounding the edge-emitting light emitting element 60, the step of mounting the cap 70 on the adhesive 110 to accommodate the edge-emitting light emitting element 60, and the step of curing the adhesive 110 to bond the cap 70 to the adhesion pattern 100. In the step of mounting the cap 70 on the adhesive 110 to accommodate the edge-emitting light emitting element 60, the adhesive 110 is formed between the cap 70 and the adhesion pattern 100 to include the thin adhesion layer 111, which is located on the inner part of the adhesion pattern 100, and the thick adhesion layer 112, which is located on the outer part of the adhesion pattern 100 and is greater in thickness than the thin adhesion layer 111.

In this structure, gas produced from the adhesive 110 is readily released from the thick adhesion layer 112 to the outside of the adhesive 110. Thus, the adhesive 110 fills the space between the adhesion pattern 100 and the cap 70 in the Z-direction with no void. As a result, the area in which the adhesion pattern 100 bonds the cap 70 with the adhesive 110 is increased. This increases the bonding strength between the adhesion pattern 100 and the cap 70 with the adhesive 110.
(2-8) The adhesion pattern 100 includes the high step 101, which includes the inner part of the pattern layer 105, and the low step 102, which includes the outer part of the pattern layer 105 and is smaller in thickness than the inner part of the pattern layer 105. The step of forming the adhesion pattern 100 includes a step of forming the upper surface of the low step 102 having a greater surface roughness than the upper surface of the high step 101. In the step of forming the adhesion pattern 100, the high step 101 and the low step 102 are formed by thinning the outer part of the pattern layer 105 using laser irradiation or etching.

With this structure, the thick adhesion layer 112 of the adhesive 110 has the anchor effect between the upper surface of the low step 102 and the cap 70 to increase the bonding strength between the adhesion pattern 100 and the cap 70. In addition, the low step 102 is formed by laser radiation or etching so that the upper surface of the low step 102 has a greater surface roughness than the upper surface of the high step 101. This eliminates the need for a step dedicated to roughening of the upper surface of the low step 102, thereby simplifying the manufacturing step.
(2-9) In the step of applying the adhesive 110 to the adhesion pattern 100, the adhesive 110 is applied to the low step 102 without being applied to the high step 101.

In this structure, when the cap 70 is mounted on the adhesive 110, the adhesive 110 on the low step 102 is moved toward the high step 101. Thus, the thin adhesion layer 111 is readily formed between the high step 101 and the cap 70.

### Modified Examples

The above embodiments may be modified as described below. The modified examples described below may be combined with one another as long as there is no technical inconsistency.

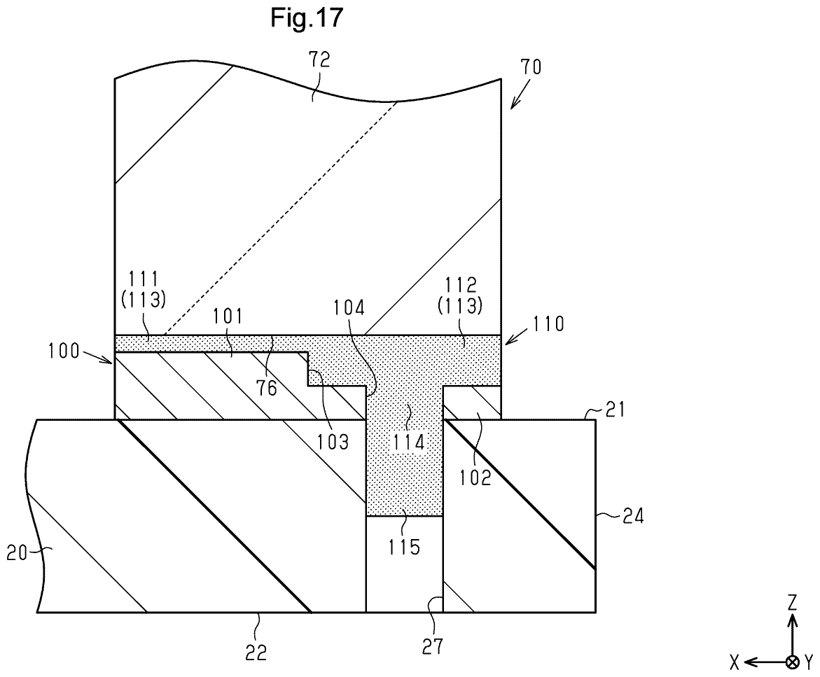

The first embodiment may be combined with the second embodiment. In an example, as shown in FIG. 17, the adhesion pattern 100 may have a pattern through hole 104. The substrate 20 may have a substrate through hole 27 that is connected to the pattern through hole 104. In the example shown in FIG. 17, the pattern through hole 104 is formed in the low step 102 of the adhesion pattern 100. In an example, multiple pattern through holes 104 are arranged. In an example, although not shown in FIG. 17, the pattern through holes 104 are formed in four corners of the adhesion pattern 100 having the form of a rectangular frame. The pattern through hole 104 is separated from the step wall 103 in the width-wise direction of the adhesion pattern 100. The substrate through hole 27 is arranged so as to be connected to the pattern through hole 104 in the same manner as the first embodiment. Hence, for example, multiple substrate through holes 27 are arranged. In an example, the pattern through hole 104 and the substrate through hole 27 are each circular in plan view.

The adhesive 110 includes a surface adhesive portion 113, a pattern adhesive portion 114, and a substrate adhesive portion 115 in the same manner as the adhesive 90 of the first embodiment. The surface adhesive portion 113 is in contact with the upper surface of the high step 101, the upper surface of the low step 102, and the step wall 103. The surface adhesive portion 113 includes the thin adhesion layer 111 and the thick adhesion layer 112. The pattern adhesive portion 114 fills the pattern through hole 104. In an example, the pattern adhesive portion 114 is in contact with the entire wall surface of the pattern through hole 104. The pattern adhesive portion 114 is formed continuously with the thick adhesion layer 112. The substrate adhesive portion 115 penetrates into the end portion of the substrate through hole 27 located close to the substrate front surface 21 in the Z-direction. Thus, the adhesive 110 bonds the cap 70, the adhesion pattern 100, and the substrate 20.

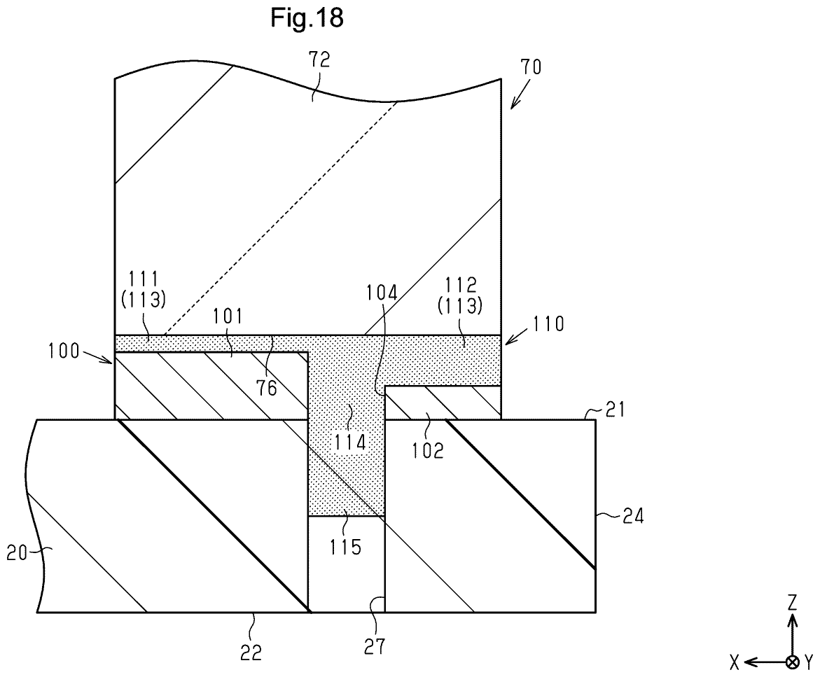

The positions of the substrate through hole 27 and the pattern through hole 34 relative to the adhesion pattern 100 may be changed in any manner. In a first example, as shown in FIG. 18, the pattern through hole 104 may be formed in both the high step 101 and the low step 102 of the adhesion pattern 100. That is, the pattern through hole 104 may extend over the step wall 103 (refer to FIG. 17). The pattern adhesive portion 114 of the adhesive 110 is formed continuously with the thick adhesion layer 112.

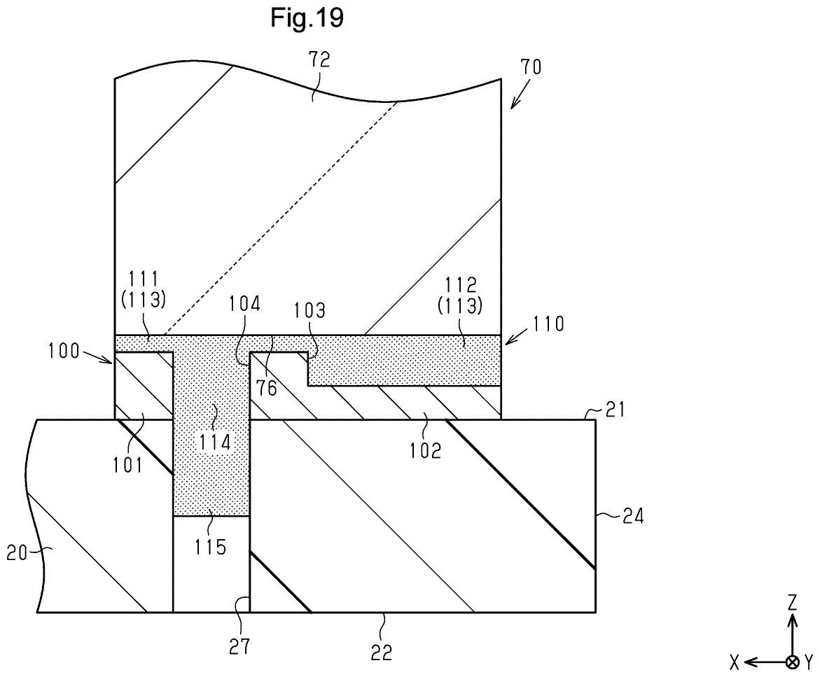

In a second example, as shown in FIG. 19, the pattern through hole 104 is formed in the high step 101 of the adhesion pattern 100. The pattern through hole 104 is separated from the step wall 103 in the width-wise direction of the adhesion pattern 100. The pattern adhesive portion 114 of the adhesive 110 is formed continuously with the thin adhesion layer 111.

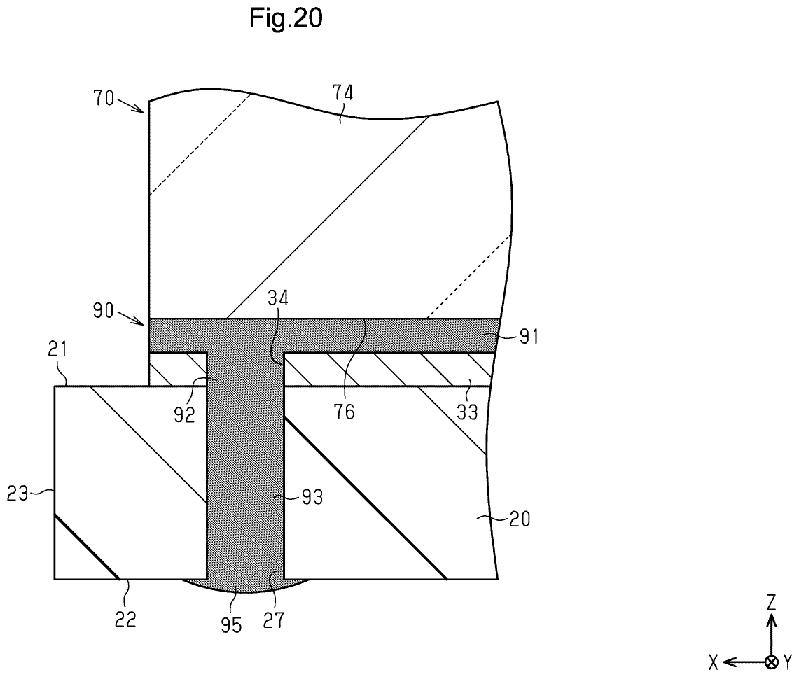

In the first embodiment, the position of the adhesive 90 that fills the substrate through hole 27 in the Z-direction may be changed in any manner. In an example, as shown in FIG. 20, the adhesive 90 may fill the entire substrate through hole 27. In the example shown in FIG. 20, the adhesive 90 includes a projection 95 projecting from the substrate back surface 22. The projection 95 has a distal surface located closer to the substrate back surface 22 than to the back electrodes 40. In an example, the projection 95 is formed on the open edge of the substrate back surface 22 defining the substrate through hole 27.

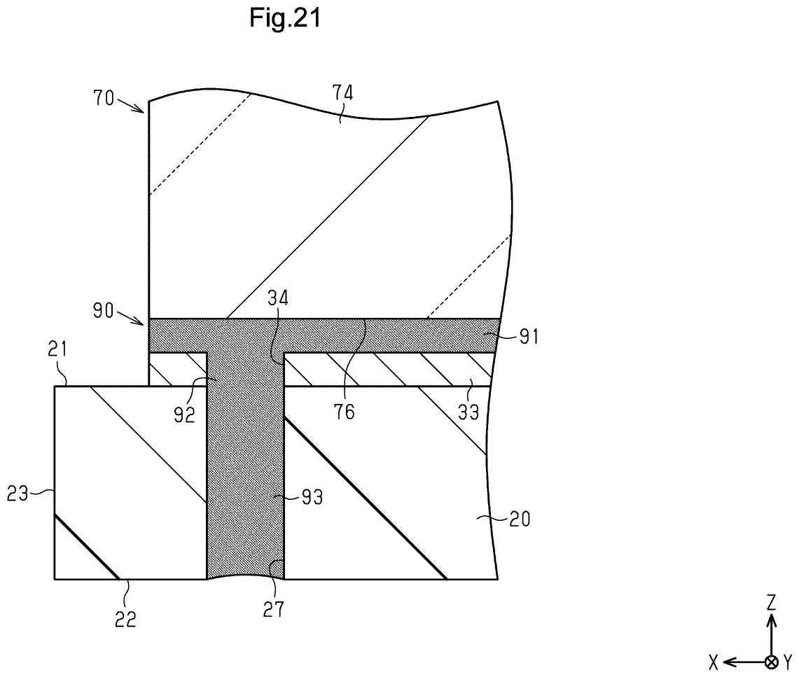

As shown in FIG. 21, the substrate adhesive portion 93 of the adhesive 90 fills the entire substrate through hole 27 without projecting from the substrate back surface 22. In an example, the distal surface of the substrate adhesive portion 93 may be concave. In another example, the distal surface of the substrate adhesive portion 93 may be convex.

Alternatively, the adhesive 90 may fill the pattern through hole 34 without filling the substrate through hole 27. That is, the adhesive 90 may include the pattern adhesive portion 92 without including the substrate adhesive portion 93.

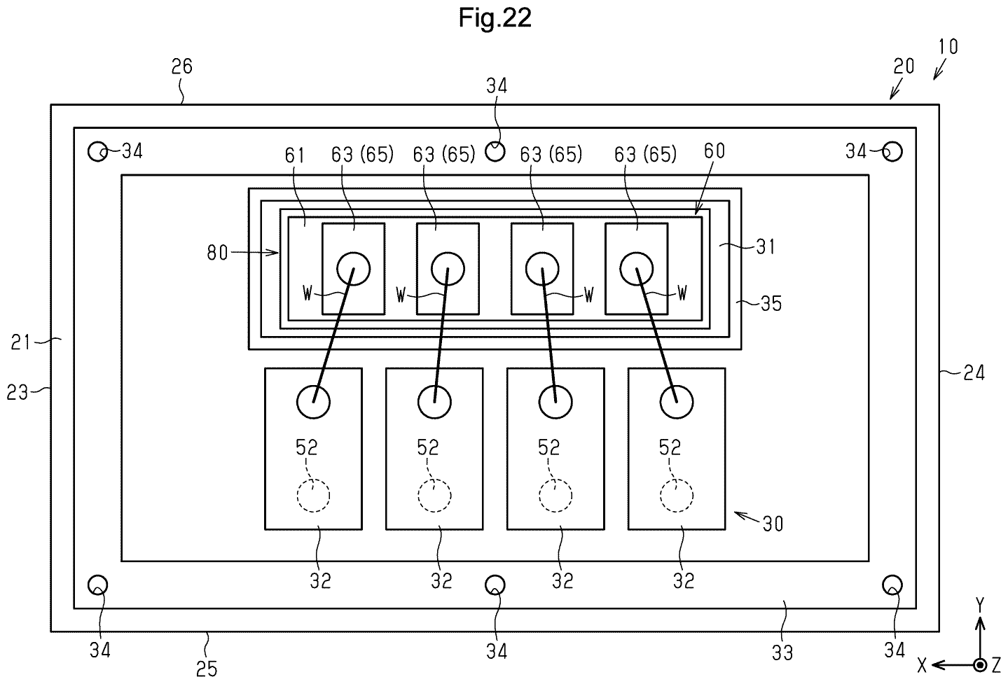

In the first embodiment, the number of substrate through holes 27 and the number of pattern through holes 34 may be changed in any manner. In an example, as shown in FIG. 22, six pattern through holes 34 may be arranged. The pattern through holes 34 may be located at the four corners of the adhesion pattern 33 and the center, in the X-direction, of each portion of the adhesion pattern 33 extending in the X-direction. Although not shown in the drawings, the substrate through holes 27 are arranged so as to be connected to the pattern through holes 34. Alternatively, the number of substrate through holes 27 and the number of pattern through holes 34 may each be one. In this case, the substrate through hole 27 is connected to the pattern through hole 34.

In the first embodiment, the number of pattern through holes 34 may be greater than the number of substrate through holes 27. In an example, as shown in FIG. 22, the pattern through holes 34 may be located at the four corners of the adhesion pattern 33, having the form of a rectangular frame, and the center, in the X-direction, of each portion of the adhesion pattern 33 extending in the X-direction. In comparison, as shown in FIG. 3, the substrate through holes 27 are arranged to overlap the four corners of the adhesion pattern 33 having the form of a rectangular frame in plan view. The four substrate through holes 27 are separately connected to the four pattern through holes 34 that are arranged at the four corners of the adhesion pattern 33.

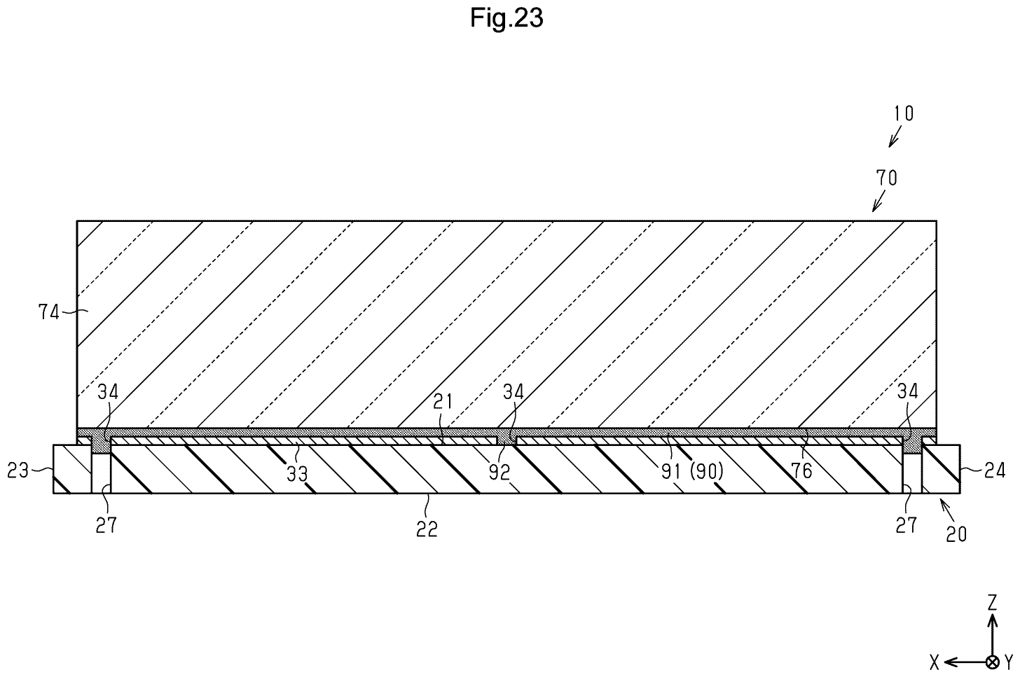

As shown in FIG. 23, of the three pattern through holes 34, the center pattern through hole 34 in the X-direction may be formed in the adhesion pattern 33, but a corresponding substrate through hole 27 may not be formed in the substrate 20. In this case, the center pattern through hole 34 is formed to expose the substrate front surface 21. The pattern adhesive portion 92 of the adhesive 90 is in contact with the substrate front surface 21.

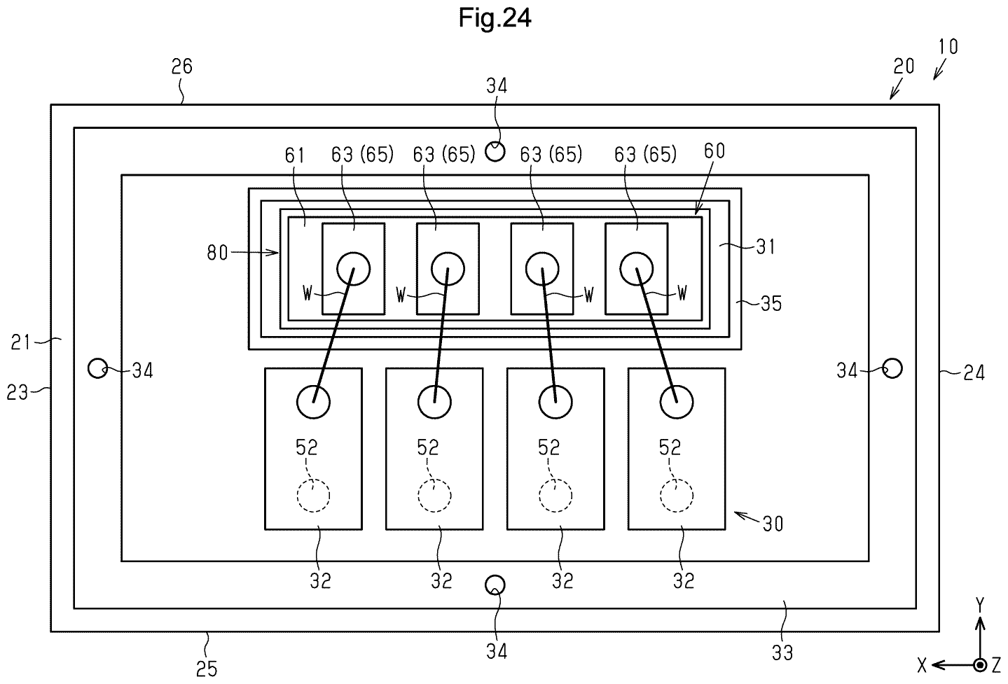

In the first embodiment, the positions of the pattern through holes 34 and the substrate through holes 27 may be changed in any manner. In an example, as shown in FIG. 24, the pattern through holes 34 and the substrate through holes 27 may be arranged in the center, in the X-direction, of each side of the adhesion pattern 33 extending in the X-direction and the center, in the Y-direction, of each side of the adhesion pattern 33 extending in the Y-direction. Preferably, the distance between adjacent ones of the pattern through holes 34 along the perimeter of the adhesion pattern 33 is the same.

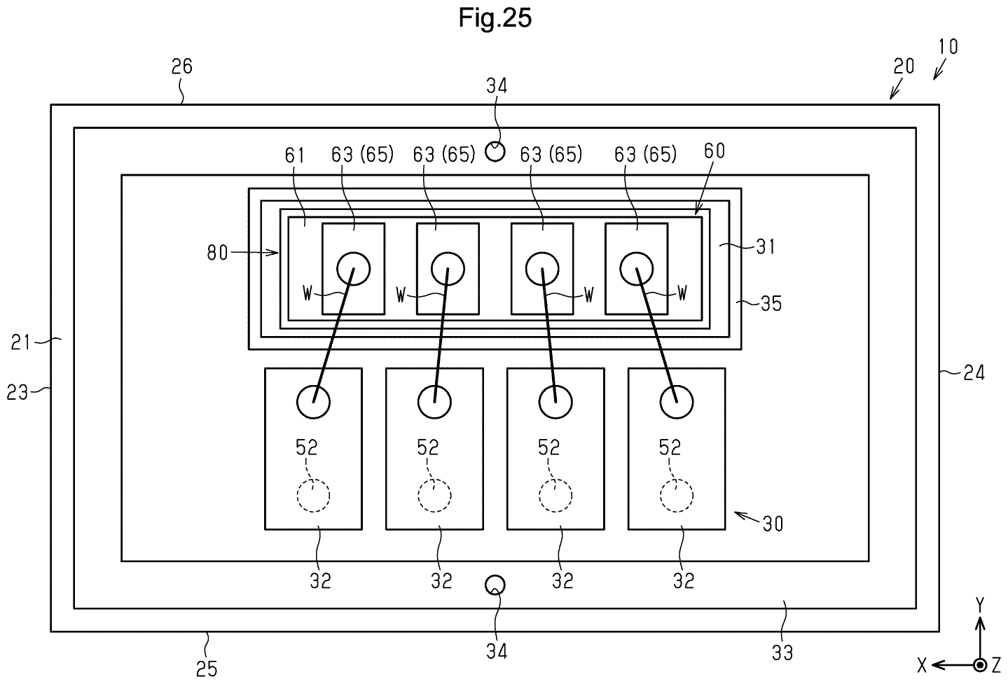

In another example, as shown in FIG. 25, the pattern through holes 34 and the substrate through holes 27 may be arranged in the center, in the X-direction, of each side of the adhesion pattern 33 extending in the X-direction but not arranged in the center, in the Y-direction, of each side of the adhesion pattern 33 extending in the Y-direction. That is, the pattern through holes 34 may be arranged in the longitudinal center of the adhesion pattern 33. The substrate through holes 27, which are connected to the pattern through holes 34, are arranged in portions of the substrate 20 overlapping the longitudinal center of the adhesion pattern 33 in plan view.

In another example, although not shown, the pattern through holes 34 and the substrate through holes 27 may be arranged in the center, in the Y-direction, of each side of the adhesion pattern 33 extending in the Y-direction but not arranged in the center, in the X-direction, of each side of the adhesion pattern 33 extending in the X-direction. That is, the pattern through holes 34 may be arranged in the lateral center of the adhesion pattern 33. The substrate through holes 27, which are connected to the pattern through holes 34, are arranged in portions of the substrate 20 overlapping the lateral center of the adhesion pattern 33 in plan view.

In the first embodiment, the pattern through hole 34 and the substrate through hole 27 may have different diameters.

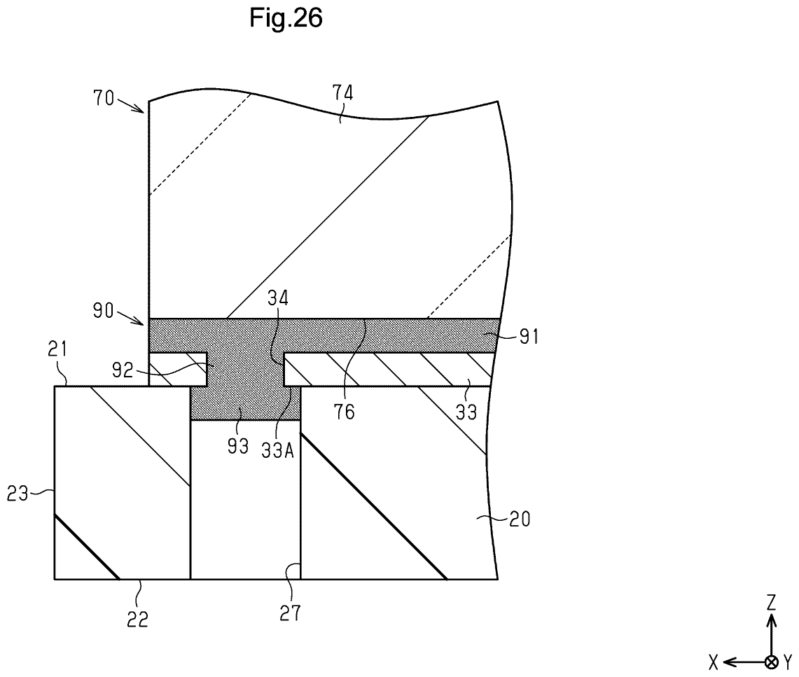

In a first example, as shown in FIG. 26, the substrate through hole 27 has a larger diameter than the pattern through hole 34. In this case, the adhesion pattern 33 includes a back surface 33A, and the substrate adhesive portion 93 of the adhesive 90 is in contact with the back surface 33A.

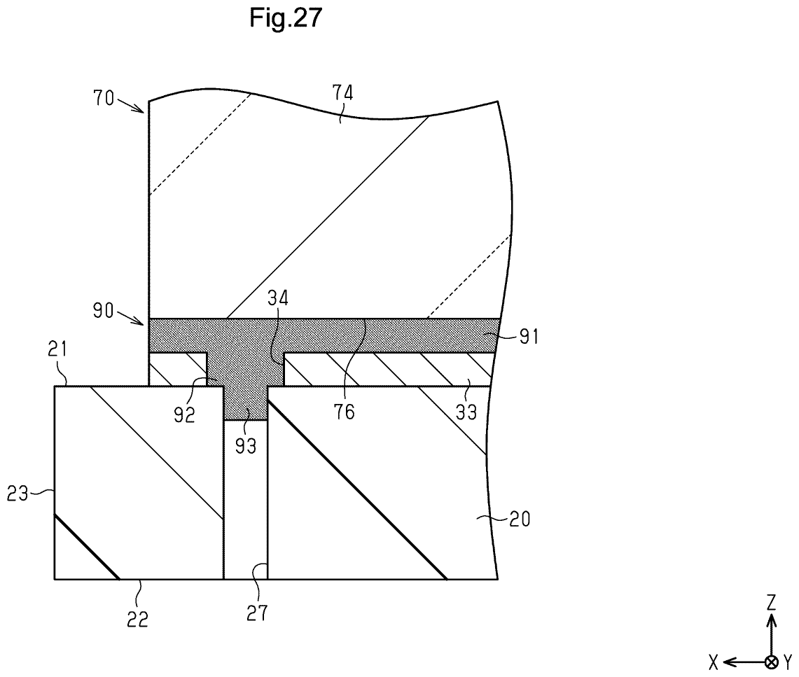

In a second example, as shown in FIG. 27, the pattern through hole 34 may have a larger diameter than the substrate through hole 27. In this case, the pattern adhesive portion 92 of the adhesive 90 is in contact with the substrate front surface 21 of the substrate 20.

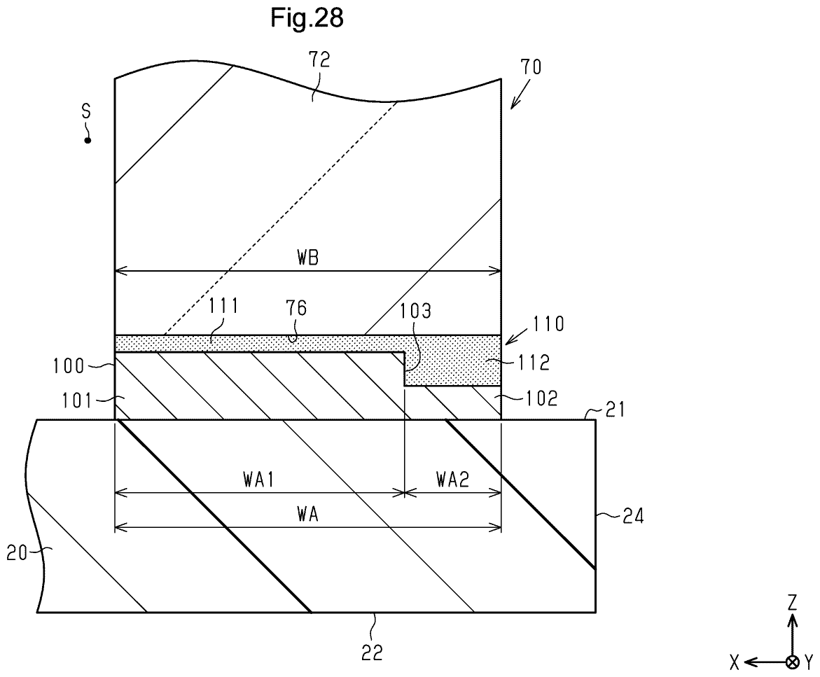

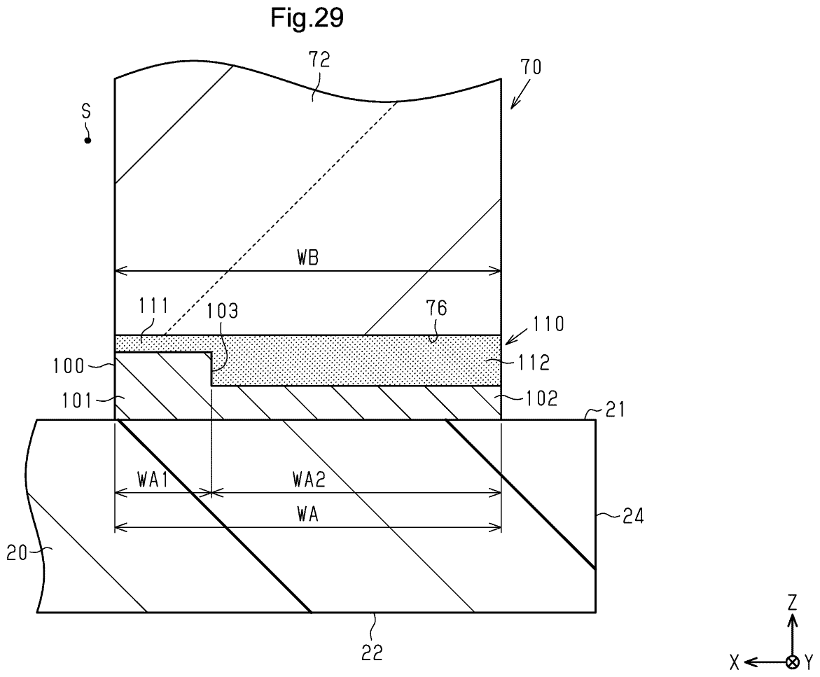

In the second embodiment, the width-wise dimension WA1 of the high step 101 may differ from the width-wise dimension WA2 of the low step 102. In a first example, as shown in FIG. 28, the width-wise dimension WA1 of the high step 101 may be greater than the width-wise dimension WA2 of the low step 102. In a second example, as shown in FIG. 29, the width-wise dimension WA2 of the low step 102 may be greater than the width-wise dimension WA1 of the high step 101.

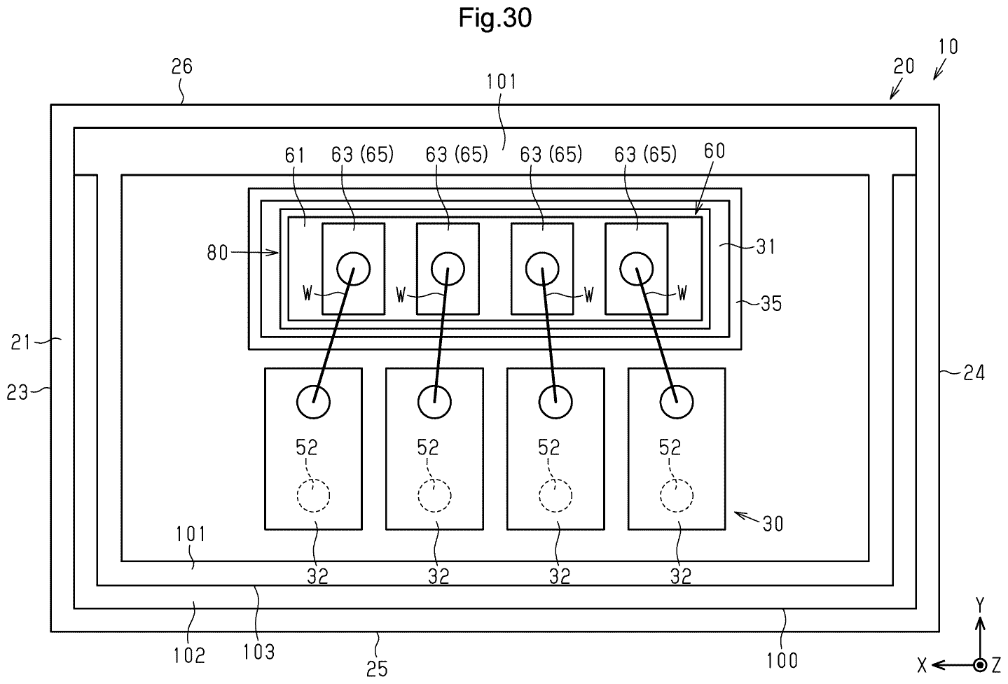

In the second embodiment, the formation region of the low step 102 may be changed in any manner. In an example, as shown in FIG. 30, the low step 102 may be omitted from a portion of the adhesion pattern 33 where the fourth side wall 74 of the cap 70 is arranged (portion of the adhesion pattern 33 located close to the fourth substrate side surface 26 of the substrate 20). In other words, the low step 102 may be omitted from a portion of the adhesion pattern 33 where the side wall allowing for passage of laser beams emitted from the edge-emitting light emitting element 60 is arranged. In an example, the high step 101 forms the portion of the adhesion pattern 33 where the fourth side wall 74 of the cap 70 is arranged. The low step 102 forms portions of the adhesion pattern 33 where the first to third side walls 71 to 73 of the cap 70 are arranged. In the same manner as the second embodiment, the low step 102 is arranged on the outer part of the adhesion pattern 33 in the width-wise direction. In the portions of the adhesion pattern 33 where the first to third side walls 71 to 73 of the cap 70 are arranged, the high step 101 is arranged on the inner part of the adhesion pattern 33 in the width-wise direction.

In the second embodiment, the upper surface of the low step 102 and the upper surface of the high step 101 may have the same surface roughness.

In the second embodiment, the adhesive 110 may not be in contact with the step wall 103.

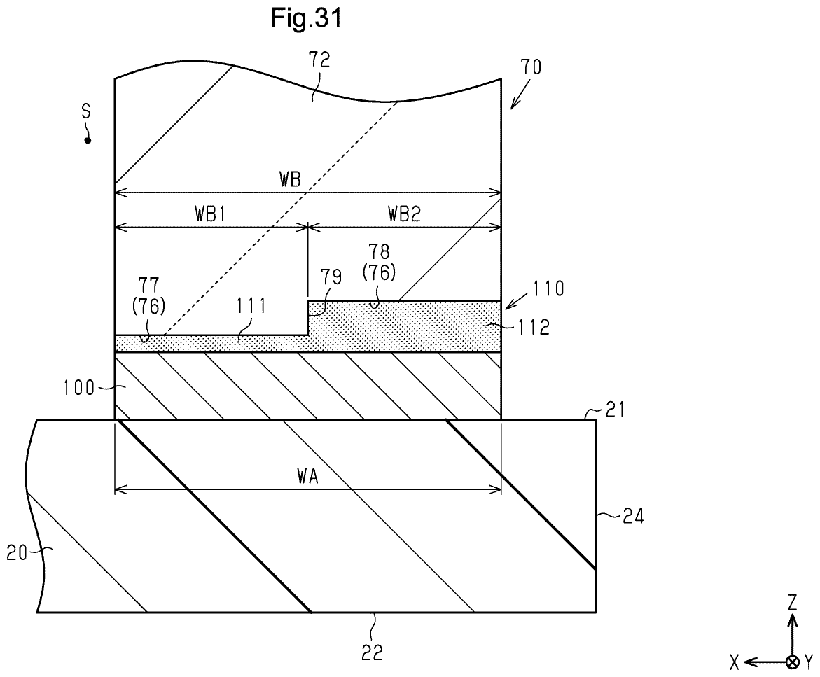

In the second embodiment, the shape of the open-end surfaces 76 of the first to fourth side walls 71 to 74 of the cap 70 may be changed in any manner. In an example, as shown in FIG. 31, the open-end surface 76 of the fourth side wall 74 includes an inner end surface 77 arranged in an inner part of the open-end surface 76 and an outer end surface 78 arranged in an outer part of the open-end surface 76. The outer end surface 78 is separated from the adhesion pattern 100 in the Z-direction farther than the inner end surface 77 is. The open-end surface 76 includes a step wall 79 located between the inner end surface 77 and the outer end surface 78. In the example shown in FIG. 31, the width-wise dimension WB1 of the inner end surface 77 is equal to the width-wise dimension WB2 of the outer end surface 78. The width-wise dimension WB1 of the inner end surface 77 extends in a direction orthogonal to the direction in which the inner end surface 77 extends in plan view. The width-wise dimension WB2 of the outer end surface 78 extends in a direction orthogonal to the direction in which the outer end surface 78 extends in plan view. The width-wise dimension WB1 of the inner end surface 77 and the width-wise dimension WB2 of the outer end surface 78 may be changed in any manner. In an example, the width-wise dimension WB1 of the inner end surface 77 may be larger than the width-wise dimension WB2 of the outer end surface 78. The width-wise dimension WB2 of the outer end surface 78 may be larger than the width-wise dimension WB1 of the inner end surface 77.

In the example shown in FIG. 31, the adhesion pattern 100 may have a uniform thickness, for example, in the width-wise direction. That is, the low step 102 and the step wall 103 may be omitted from the adhesion pattern 100.

The adhesive 110 includes the thin adhesion layer 111 and the thick adhesion layer 112 in the same manner as the second embodiment. The thin adhesion layer 111 is located between the adhesion pattern 100 and the inner end surface 77 of the cap 70. In an example, the thin adhesion layer 111 is in contact with the entire inner end surface 77 of the first to fourth side walls 71 to 74 of the cap 70. The thick adhesion layer 112 is located between the adhesion pattern 100 and the outer end surface 78 of the cap 70. In an example, the thick adhesion layer 112 is in contact with the entire outer end surface 78 of the first to fourth side walls 71 to 74 of the cap 70. The adhesive 110 is in contact with the step wall 79 of the cap 70. In an example, the adhesive 110 is in contact with the entire surface of the step wall 79 of the first to fourth side walls 71 to 74 of the cap 70.

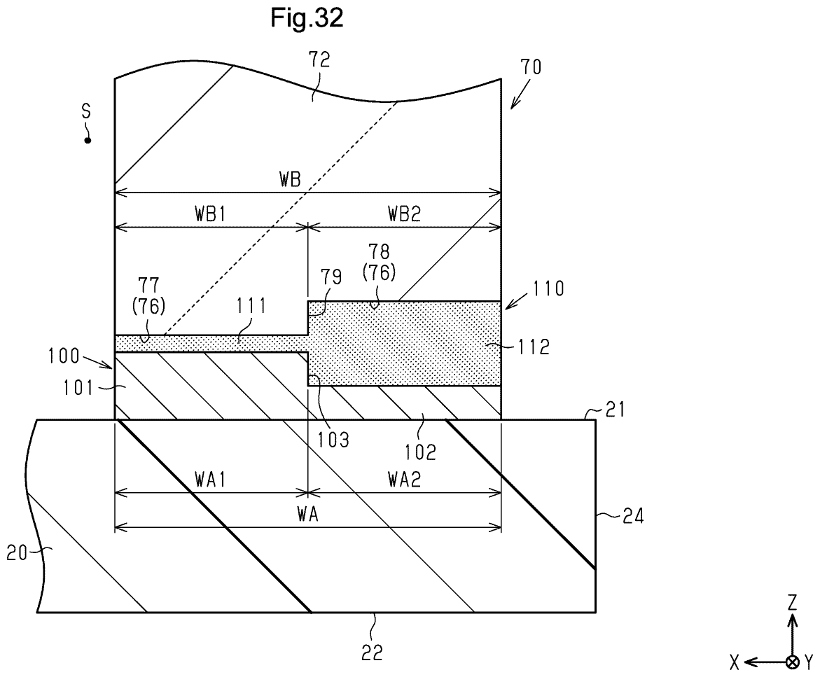

In another example, as shown in FIG. 32, the adhesion pattern 100 may include a high step 101, a low step 102, and a step wall 103 in the same manner as the second embodiment. In this case, the thin adhesion layer 111 of the adhesive 110 is located between the high step 101 of the adhesion pattern 100 and the inner end surface 77 of the cap 70. In an example, the thin adhesion layer 111 is in contact with the entire inner end surface 77 of the first to fourth side walls 71 to 74 of the cap 70 and the entire upper surface of the high step 101 of the adhesion pattern 100. The thick adhesion layer 112 of the adhesive 110 is located between the low step 102 of the adhesion pattern 100 and the outer end surface 78 of the cap 70. In an example, the thick adhesion layer 112 is in contact with the entire outer end surface 78 of the first to fourth side walls 71 to 74 of the cap 70 and the entire upper surface of the low step 102 of the adhesion pattern 100. The adhesive 110 is in contact with the step wall 79 of the cap 70 and the step wall 103 of the adhesion pattern 100. In an example, the adhesive 110 is in contact with the entire surface of the step wall 79 of the first to fourth side walls 71 to 74 of the cap 70 and the entire surface of the step wall 103 of the adhesion pattern 100.

The distance between the inner end surface 77 and the outer end surface 78 in the open-end surface 76 of the cap 70 in the Z-direction may be changed in any manner. In an example, the distance between the inner end surface 77 and the outer end surface 78 of the open-end surface 76 in the Z-direction is greater than the distance between the upper surface of the high step 101 and the upper surface of the low step 102 of the adhesion pattern 100 in the Z-direction. In another example, the distance between the inner end surface 77 and the outer end surface 78 of the open-end surface 76 in the Z-direction is less than the distance between the upper surface of the high step 101 and the upper surface of the low step 102 of the adhesion pattern 100 in the Z-direction. The cap 70 shown in FIGS. 31 and 32 may be applied to the first embodiment.

The outer end surface 78 of the cap 70 may have a larger surface roughness than the inner end surface 77. In this case, a roughening process may be performed on the outer end surface 78. Examples of the roughening process include sandblasting and wet blasting.

The open-end surface 76 of the fourth side wall 74 of the cap 70 may be flat and be orthogonal to the Z-direction. More specifically, the open-end surface 76 of the side wall of the cap 70 allowing for passage of laser beams from the edge-emitting light emitting element 60 may be flat and be orthogonal to the Z-direction.

In the first embodiment, the adhesive 90 is not limited to an ultraviolet/thermal dual-curing adhesive and may be changed in any manner. In an example, the adhesive 90 may be an ultraviolet curing adhesive. In this case, in the step of curing the adhesive 90, the adhesive 90 is irradiated from the upper wall 75 of the cap 70 with ultraviolet rays. The cap 70 is formed from a material that allows for passage of ultraviolet rays. Thus, when the adhesive 90 is irradiated with ultraviolet rays that are transmitted through the cap 70, the adhesive 90 is entirely cured.

In the second embodiment, the step of forming the adhesion pattern 100 may include, separately from the step of forming the low step 102, a step of forming the upper surface of the low step 102 having a greater surface roughness than the upper surface of the high step 101. In an example, in the step of forming the upper surface of the low step 102 having a greater surface roughness than the upper surface of the high step 101, the upper surface of the high step 101 is masked, and then the brown process may be performed on the upper surface of the low step 102. As a result, fine irregularities are formed in the upper surface of the low step 102. In addition, fine irregularities may be formed in a side surface of the step wall 103 in the same manner as the upper surface of the low step 102.

In the second embodiment, in the step of applying the adhesive 110 to the adhesion pattern 100, the adhesive 110 may be applied to only the high step 101 of the adhesion pattern 100. Alternatively, the adhesive 110 may be applied to the high step 101 and the low step 102 of the adhesion pattern 100.

In each embodiment, the relationship between the width-wise dimension WA of the adhesion patterns 33 and 100 and the width-wise dimension WB of the first to fourth side walls 71 to 74 of the cap 70 may be changed in any manner. In an example, the width-wise dimension WA of the adhesion patterns 33 and 100 may be larger than the width-wise dimension WB of the first to fourth side walls 71 to 74 of the cap 70. In another example, the width-wise dimension WA of the adhesion patterns 33 and 100 may be smaller than the width-wise dimension WB of the first to fourth side walls 71 to 74 of the cap 70.

In the second embodiment, the adhesive 110 may be, for example, an ultraviolet curing adhesive. In this case, in the step of curing the adhesive 110 to bond the cap 70 to the adhesion pattern 100, the adhesive 110 is irradiated from the upper wall 75 of the cap 70 with ultraviolet rays. The cap 70 is formed from a material that allows for passage of ultraviolet rays. Thus, when the adhesive 110 is irradiated with ultraviolet rays that are transmitted through the cap 70, the adhesive 110 is cured.

In each embodiment, in plan view, the shape of the adhesion patterns 33 and 100 may be changed in any manner. In an example, in plan view, the adhesion patterns 33 and 100 may have the form of a square frame. In an example, in plan view, the adhesion patterns 33 and 100 are not limited to the rectangular shape and may have the form of an oblong (athletic track-shaped) frame, an elliptical frame, or a circular frame.

In each embodiment, the edge-emitting light emitting element 60 is used as a semiconductor light emitting element. However, the semiconductor light emitting element is not limited to such a configuration. The semiconductor light emitting element may be a surface-emitting light emitting element. An example of the surface-emitting light emitting element is a vertical cavity surface emitting laser (VCSEL). In this case, the cap 70 may be configured so that the upper wall 75 has a transparent surface. In contrast, the fourth side wall 74 of the cap 70 may be translucent in the same manner as the first to third side walls 71 to 73. The semiconductor light emitting element may be a light emitting diode (LED).

In each embodiment, the cap 70 may be formed from, for example, a material that does not allow for passage of ultraviolet rays. In an example, the cap 70 may be formed from, for example, metal or ceramic. The cap 70 may be formed from a light-blocking material. In this case, the cap 70 may have an opening that allows for passage of laser beams from the edge-emitting light emitting element 60.

In the present disclosure, the term “on” includes the meaning of “above” in addition to the meaning of “on” unless otherwise clearly indicated in the context. Accordingly, for example, the expression of “first element mounted on second element” may mean that the first element is placed directly on the second element in one embodiment and mean that the first element is placed above the second element without contacting the second element in another embodiment. In other words, the term “on” does not exclude a structure in which another component is formed between the first component and the second component.

The Z-direction as referred to in the present disclosure does not necessarily have to be the vertical direction and does not necessarily have to exactly coincide with the vertical direction. Accordingly, in the structures of the present disclosure, “up” and “down” in the Z-direction as referred to in this specification is not limited to “up” and “down” in the vertical direction. For example, the X-direction may be the vertical direction. Alternatively, the Y-direction may be the vertical direction.

### CLAUSES

Technical concepts that can be understood from each of the above embodiments and modified examples will now be described. The reference signs of the components in the embodiments are given to the corresponding components in clauses with parentheses. The reference signs are used as examples to facilitate understanding, and the components in each clause are not limited to those components given with the reference signs.
[Clause A1] A semiconductor light emitting device (10), including:
a substrate (20);
a semiconductor light emitting element (60) mounted on the substrate (20);
a cap (70) configured to accommodate the semiconductor light emitting element (60);
an adhesive (90) configured to bond the cap (70) and the substrate (20), the substrate (20) having a substrate through hole (27) that is configured to overlap the adhesive (90) as viewed in a thickness-wise direction (Z-direction) of the substrate (20); and
an adhesion pattern (33) formed on the substrate (20) to surround the semiconductor light emitting element (60) as viewed in the thickness-wise direction (Z-direction) of the substrate (20), in which
the adhesive (90) is disposed on the adhesion pattern (33) so as to bond the adhesion pattern (33) and the cap (70),
the adhesion pattern (33) has a pattern through hole (34) that is connected to the substrate through hole (27), and
a portion of the adhesive (90) penetrates into the pattern through hole (34).
[Clause A2] The semiconductor light emitting device according to clause A1, in which the adhesive (90) includes an ultraviolet/thermal dual-curing adhesive or an ultraviolet curing adhesive.
[Clause A3] The semiconductor light emitting device according to clause A1 or A2, in which
the substrate through hole (27) is one of multiple substrate through holes (27), and
the pattern through hole (34) is one of multiple pattern through holes (34).
[Clause A4] The semiconductor light emitting device according to any one of clauses A1 to A3, in which the adhesive (90) penetrates into the substrate through hole (27).
[Clause A5] The semiconductor light emitting device according to any one of clauses A1 to A4, in which
as viewed in the thickness-wise direction (Z-direction) of the substrate (20), the adhesion pattern (33) is rectangular-frame-shaped, and the pattern through hole (34) is arranged at four corners of the adhesion pattern (33).
[Clause A6] The semiconductor light emitting device according to clause A5, in which
as viewed in the thickness-wise direction (Z-direction) of the substrate (20), the adhesion pattern (33) is rectangular-frame-shaped and extends in a longitudinal direction and a lateral direction, and
the pattern through hole (34) is further arranged at a center of the adhesion pattern (33) in the longitudinal direction.
[Clause A7] The semiconductor light emitting device according to any one of clauses A1 to A6, in which
the cap (70) includes a side wall (71 to 74) surrounding the semiconductor light emitting element (60) as viewed in the thickness-wise direction (Z-direction) of the substrate (20), and
the adhesive (90) is in contact with an open-end surface (76) of the side wall (71 to 74) and the adhesion pattern (33) to bond the cap (70) and the adhesion pattern (33).
[Clause A8] The semiconductor light emitting device according to any one of clauses A1 to A7, in which
the semiconductor light emitting device includes an edge-emitting light emitting element (60),
the cap (70) is box-shaped, and
light emitted from the edge-emitting light emitting element (60) is configured to exit the semiconductor light emitting device (10) through a side wall (71 to 74) of the cap (70).
[Clause A9] The semiconductor light emitting device according to any one of clauses A1 to A8, in which the adhesive (90) entirely fills the substrate through hole (27) and projects from a substrate back surface (22) of the substrate (20) to form a projection on the substrate back surface (22) around the substrate through hole (27).
[Clause A10] The semiconductor light emitting device according to any one of clauses A1 to A8, in which the adhesive (90) fills the substrate through hole (27) without projecting from a substrate back surface (22) of the substrate (20).
[Clause A11] The semiconductor light emitting device (10) according to any one of clauses A1 to A10, in which the cap (70) is formed from at least one of resin, glass, metal, and ceramic.
[Clause A12] A method for manufacturing a semiconductor light emitting device (10), the method including:
preparing a substrate (20) that includes a substrate front surface (21) and a substrate back surface (22) located at opposite sides of the substrate (20), in which an adhesive pattern (33) shaped as a frame is formed on the substrate front surface (21), a pattern through hole (34) is formed in the adhesion pattern (33), and a substrate through hole (27) connected to the pattern through hole (34) is formed;
mounting a semiconductor light emitting element (60) on the substrate (20) inside the frame of the adhesion pattern (33);
applying an adhesive (90) to the adhesion pattern (33); and
mounting a cap (70) on the adhesive (90) to accommodate the semiconductor light emitting element (60), in which
in the applying the adhesive (90) to the adhesion pattern (33), the adhesive (90) is applied to the adhesive pattern (34) so as to penetrate into the pattern through hole (34).
[Clause A13] The method according to clause A12, further including:
curing the adhesive (90) exposed from the substrate through hole (27) by irradiating the adhesive (90) exposed from the substrate through hole (27) with an ultraviolet ray; and
curing entirety of the adhesive (90).
[Clause A14] The method according to clause A13, in which
the substrate through hole (27) is one of multiple substrate through holes (27),
the pattern through hole (34) is one of multiple pattern through holes (34), and
in the curing the adhesive (90) exposed from the substrate through hole (27), the adhesive (90) exposed from the multiple substrate through holes (27) is simultaneously irradiated with the ultraviolet ray.
[Clause A15] The method according to clause A13 or A14, in which the ultraviolet ray is emitted toward the substrate back surface (22).
[Clause A16] The method according to any one of clauses A13 to A15, in which in the curing entirety of the adhesive (90), the adhesive (90) is thermally cured.
[Clause A17] The method according to any one of clauses A13 to A15, in which in the curing entirety of the adhesive (90), the adhesive (90) is cured by being irradiated from the cap (70) with an ultraviolet ray.
[Clause A18] The method according to any one of clauses A12 to A17, in which in the applying the adhesive (90) to the adhesion pattern (33), the adhesive (90) is applied to the adhesion pattern (33) so as to penetrate into the substrate through hole (27) through the pattern through hole (34).
[Clause A19] A method for manufacturing a semiconductor light emitting device (10), the method including:
preparing a substrate (20) that includes a substrate front surface (21) and a substrate back surface (22) located at opposite sides of the substrate (20), in which an adhesive pattern (33) shaped as a frame is formed on the substrate front surface (21), a pattern through hole (34) is formed in the adhesion pattern (33), and a substrate through hole (27) is formed in the substrate (20) and is connected to the pattern through hole (34);
mounting a semiconductor light emitting element (60) on the substrate (20) inside the frame of the adhesion pattern (33);
applying an adhesive (90) to the adhesion pattern (33);
mounting a cap (70) on the adhesive (90) to accommodate the semiconductor light emitting element (60);
curing the adhesive (90) exposed from the substrate through hole (27) by irradiating the adhesive (90) exposed from the substrate through hole (27) with an ultraviolet ray; and
curing entirety of the adhesive (90).

### Technical Problem to Be Solved by Clause A19

When the adhesion pattern and the cap are bonded to each other by an adhesive, the cap may be bonded to the adhesion pattern in a state where the open-end surface of the cap is not parallel to the adhesion pattern and is inclined with respect to a direction orthogonal to the thickness-wise direction of the substrate due to the curing of the adhesive.

### Advantage of Clause A19

The method for manufacturing the semiconductor light emitting device according to the present disclosure avoids the bonding of the cap to the adhesion pattern in a state where the open-end surface of the cap is not parallel to the adhesion pattern and is inclined with respect to the direction orthogonal to the thickness-wise direction of the substrate due to the curing of the adhesive.
[Clause A20] The method according to clause A19, in which
the substrate through hole (27) is one of multiple substrate through holes (27),
the pattern through hole (33) is one of multiple pattern through holes (33), and
in the curing the adhesive (90) exposed from the substrate through hole (27), the adhesive (90) exposed from the multiple substrate through holes (27) is simultaneously irradiated with the ultraviolet ray.
[Clause A21] The method according to clause A19 or A20, in which the ultraviolet ray is emitted toward the substrate back surface (22).
[Clause A22] The method according to any one of clauses A19 to A21, in which the adhesive (90) includes an ultraviolet/thermal dual-curing adhesive, and in the curing entirety of the adhesive (90), the adhesive (90) is thermally cured.
[Clause A23] The method according to any one of clauses A19 to A21, in which the adhesive (90) includes an ultraviolet curing adhesive, and
in the curing entirety of the adhesive (90), the adhesive (90) is cured by being irradiated from the cap (70) with an ultraviolet ray.
[Clause B1] A semiconductor light emitting device (10), including:
a substrate (20);
a semiconductor light emitting element (60) mounted on the substrate (20);
a cap (70) configured to accommodate the semiconductor light emitting element (60);
a frame-shaped adhesion pattern (100) arranged on the substrate (20) to surround the semiconductor light emitting element (60) as viewed in the thickness-wise direction (Z-direction) of the substrate (20); and
an adhesive (110) bonding the cap (70) and the adhesion pattern (100), in which
the adhesive (110) includes
   a thin adhesive layer (111) located on an inner part of the adhesion pattern (100), and
   a thick adhesive layer (112) located on an outer part of the adhesion pattern (100) and being greater in thickness than the thin adhesive layer (111).
[Clause B2] The semiconductor light emitting device according to clause B1, in which the adhesion pattern (100) includes
   a high step (101) located in an inner part of the adhesion pattern (100), and
   a low step (102) located in an outer part of the adhesion pattern (100) and being smaller in thickness than the high step (101),
the thin adhesive layer (111) is arranged between the high step (101) and the cap (70), and
the thick adhesive layer (112) is arranged between the low step (102) and the cap (70).
[Clause B3] The semiconductor light emitting device according to clause B2, in which the adhesion pattern (100) includes a step wall (103) located between the low step (102) and the high step (101), and the adhesive (110) is in contact with the step wall (103).
[Clause B4] The semiconductor light emitting device according to clause B2 or B3, in which the low step (102) extends along an entire perimeter of the adhesion pattern (100).
[Clause B5] The semiconductor light emitting device according to any one of clauses B2 to B4, in which an upper surface of the low step (102) has a greater surface roughness than an upper surface of the high step (101).
[Clause B6] The semiconductor light emitting device according to any one of clauses B2 to B5, in which a width-wise dimension (WA2) of the low step (102) is equal to a width-wise dimension (WA1) of the high step (101).
[Clause B7] The semiconductor light emitting device according to any one of clauses B2 to B5, in which a width-wise dimension (WA2) of the low step (102) is greater than a width-wise dimension (WA1) of the high step (101).
[Clause B8] The semiconductor light emitting device according to any one of clauses B2 to B5, in which a width-wise dimension (WA2) of the low step (102) is smaller than a width-wise dimension (WA1) of the high step (101).
[Clause B9] The semiconductor light emitting device according to any one of clauses B1 to B8, in which
the cap (70) is box-shaped and is open toward the substrate (20),
the cap (70) includes a side wall (71 to 74) being frame-shaped and surrounding the semiconductor light emitting element (60) as viewed in the thickness-wise direction (Z-direction) of the substrate (20), and
the thin adhesive layer (111) and the thick adhesive layer (112) are in contact with an open-end surface (76) of the side wall (71 to 74).
[Clause B10] The semiconductor light emitting device according to clause B9, in which the open-end surface (76) includes a flat surface.
[Clause B11] The semiconductor light emitting device according to clause B9 or B10, in which a width-wise dimension (WB) of the side wall (71 to 74) of the cap (70) is equal to a width-wise dimension (WA) of the adhesion pattern (100).
[Clause B12] The semiconductor light emitting device according to any one of clauses B9 to B11, in which the semiconductor light emitting element includes an edge-emitting light emitting element (60) configured to emit light so that the light exits the semiconductor light emitting device (10) through the side wall (74) of the cap (70).
[Clause B13] The semiconductor light emitting device according to any one of clauses B2 to B8, in which
the cap (70) is box-shaped and is open toward the substrate (20),
the cap (70) includes a side wall (71 to 74) being frame-shaped and surrounding the semiconductor light emitting element (60) as viewed in the thickness-wise direction (Z-direction) of the substrate (20),
the semiconductor light emitting element includes an edge-emitting light emitting element (60) configured to emit light so that the light exits the semiconductor light emitting device (10) through the side wall (74) of the cap (70),
the thin adhesive layer (111) and the thick adhesive layer (112) are in contact with an open-end surface (76) of the side wall (71 to 74), and
the adhesion pattern (100) includes a portion located in an emission direction of the edge-emitting light emitting element (60) with respect to the edge-emitting light emitting element (60), the portion of the adhesion pattern (100) being formed of the high step (101) instead of the low step (102).
[Clause B14] A method for manufacturing a semiconductor light emitting device (10), the method including:
mounting a semiconductor light emitting element (60) on a substrate (20);
applying an adhesive (110) to a frame-shaped adhesion pattern (100) arranged on the substrate (20) and surrounding the semiconductor light emitting element (60);
mounting a cap (70) on the adhesive (110) to accommodate the semiconductor light emitting element (60); and
curing the adhesive (110) to bond the cap (70) to the adhesion pattern (100), in which
in the mounting the cap (70) on the adhesive (110) to accommodate the semiconductor light emitting element (60), the adhesive (110) is formed to include a thin adhesive layer (111) located on an inner part of the adhesion pattern (100) between the cap (70) and the adhesion pattern (100), a thick adhesive layer (112) located on an outer part of the adhesion pattern (100) between the cap (70) and the adhesion pattern (100), the thick adhesive layer (112) being greater in thickness than the thin adhesive layer (111).
[Clause B15] The method according to clause B14, in which the forming the adhesion pattern (100) includes
forming a frame-shaped pattern layer (105) having a uniform thickness, and
forming the adhesion pattern (100) by reducing a thickness of the outer part of the pattern layer (105) to be smaller than a thickness of the inner part of the pattern layer (105).
[Clause B16] The method according to clause B15, in which
the adhesion pattern (100) includes a high step (101) including the inner part of the pattern layer (105) and a low step (102) including the outer part of the pattern layer (105) and being smaller in thickness than the inner part of the pattern layer (105), and
in the applying the adhesive (110) to the adhesion pattern (100), the adhesive (110) is applied to the low step (102) without being applied to the high step (101).
[Clause B17] The method according to clause B16, in which the forming the adhesion pattern (100) includes forming an upper surface of the low step (102) having a greater surface roughness than an upper surface of the high step (101).
[Clause B18] The method according to clause B17, in which in the forming the adhesion pattern (100), the high step (101) and the low step (102) are formed by thinning the outer part of the pattern layer (105) using laser irradiation or etching.
[Clause B19] The semiconductor light emitting device according to clause B1, in which
the cap (70) is box-shaped and is open toward the substrate (20), the cap (70) includes a side wall (71 to 74) being frame-shaped and surrounding the semiconductor light emitting element (60) as viewed in the thickness-wise direction (Z-direction) of the substrate (20), and
the side wall (71 to 74) includes an open-end surface (76),
the open-end surface (76) includes
   an inner end surface (77) located in an inner part of the open-end surface (76), and
   an outer end surface (78) located in an outer part of the open-end surface (76) and separated from the adhesion pattern (100) in a thickness-wise direction (Z-direction) of the substrate (20) farther than the inner end surface (77) is,
the thin adhesive layer (111) is located between the adhesion pattern (100) and the inner end surface (77), and
the thick adhesive layer (112) is located between the adhesion pattern (100) and the outer end surface (78).
[Clause B20] The semiconductor light emitting device according to clause B1, in which
the adhesion pattern (100) includes
   a high step (101) located in an inner part of the adhesion pattern (100), and
   a low step (102) located in an outer part of the adhesion pattern (100) and being smaller in thickness than the high step (101),
the thin adhesive layer (111) is located between the high step (101) and the inner end surface (77), and
the thick adhesive layer (112) is located between the low step (102) and the outer end surface (78).
[Clause B21] The semiconductor light emitting device according to clause B20, in which
the substrate (20) has a substrate through hole (27) that overlaps the adhesive (110) as viewed in a thickness-wise direction (Z-direction) of the substrate (20),
the adhesion pattern (100) has a pattern through hole (104) that is connected to the substrate through hole (27), and
a portion of the adhesive (110) penetrates into the pattern through hole (104).
[Clause B22] The semiconductor light emitting device according to clause B21, in which
the substrate through hole (27) is one of multiple substrate through holes (27), and
the pattern through hole (104) is one of multiple pattern through holes (104).
[Clause B23] The semiconductor light emitting device according to clause B21 or B22, in which the adhesive (100) penetrates into the substrate through hole (27).
[Clause B24] The semiconductor light emitting device according to any one of clauses B1 to B13 and B19 to B23, in which the cap (70) is formed from at least one of resin, glass, metal, and ceramic.
[Clause B25] The semiconductor light emitting device according to any one of clauses B1 to B13 and B19 to B24, in which the adhesive (110) includes a thermosetting adhesive or an ultraviolet curing adhesive.
[Clause B26] The method according to any one of clauses B14 to B18, in which in the mounting the cap (70) on the adhesive (110) to accommodate the semiconductor light emitting element (60), the adhesive (110) applied to the low state (102) is moved by the cap (70) to the high step (101) to form the thin adhesive layer (111).
[Clause B27] The method according to any one of clauses B14 to B18 and B26, in which
the adhesive (110) includes a thermosetting adhesive,
in the curing the adhesive (110) to bond the cap (70) to the adhesion pattern (100), the adhesive (110) is thermally cured.
[Clause B28] The method according to any one of clauses B14 to B18 and B26, in which
the adhesive (110) includes an ultraviolet curing adhesive,
in the curing the adhesive (110) to bond the cap (70) to the adhesion pattern (100), the adhesive (110) is cured by being irradiated from the cap (70) with an ultraviolet ray.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor light emitting device, comprising:
a substrate;
a semiconductor light emitting element mounted on the substrate;
a cap configured to accommodate the semiconductor light emitting element;
an adhesive configured to bond the cap and the substrate, the substrate having a substrate through hole that is configured to overlap the adhesive as viewed in a thickness-wise direction of the substrate; and
an adhesion pattern formed on the substrate to surround the semiconductor light emitting element as viewed in the thickness-wise direction of the substrate, wherein
the adhesive is disposed on the adhesion pattern so as to bond the adhesion pattern and the cap,
the adhesion pattern has a pattern through hole that is connected to the substrate through hole, and
a portion of the adhesive penetrates into the pattern through hole.

2. The semiconductor light emitting device according to claim 1, wherein the adhesive includes an ultraviolet/thermal dual-curing adhesive or an ultraviolet curing adhesive.

3. The semiconductor light emitting device according to claim 1, wherein
the substrate through hole is one of multiple substrate through holes, and
the pattern through hole is one of multiple pattern through holes.

4. The semiconductor light emitting device according to claim 1, wherein the adhesive penetrates into the substrate through hole.

5. The semiconductor light emitting device according to claim 1, wherein
as viewed in the thickness-wise direction of the substrate, the adhesion pattern is rectangular-frame-shaped, and
the pattern through hole is arranged at four corners of the adhesion pattern.

6. The semiconductor light emitting device according to claim 5, wherein
as viewed in the thickness-wise direction of the substrate, the adhesion pattern is rectangular-frame-shaped and extends in a longitudinal direction and a lateral direction, and
the pattern through hole is further arranged at a center of the adhesion pattern in the longitudinal direction.

7. The semiconductor light emitting device according to claim 1, wherein
the cap includes a side wall surrounding the semiconductor light emitting element as viewed in the thickness-wise direction of the substrate, and
the adhesive is in contact with an open-end surface of the side wall and the adhesion pattern to bond the cap and the adhesion pattern.

8. The semiconductor light emitting device according to claim 1, wherein
the semiconductor light emitting device includes an edge-emitting light emitting element,
the cap is box-shaped, and
light emitted from the edge-emitting light emitting element is configured to exit the semiconductor light emitting device through a side wall of the cap.

9. The semiconductor light emitting device according to claim 1, wherein the adhesive entirely fills the substrate through hole and projects from a substrate back surface of the substrate to form a projection on the substrate back surface around the substrate through hole.

10. The semiconductor light emitting device according to claim 1, wherein the adhesive fills the substrate through hole without projecting from a substrate back surface of the substrate.

11. The semiconductor light emitting device according to claim 1, wherein the cap is formed from at least one of resin, glass, metal, and ceramic.

12. A method for manufacturing a semiconductor light emitting device, the method comprising:
preparing a substrate that includes a substrate front surface and a substrate back surface located at opposite sides of the substrate, wherein an adhesive pattern shaped as a frame is formed on the substrate front surface, a pattern through hole is formed in the adhesion pattern, and a substrate through hole connected to the pattern through hole is formed;
mounting a semiconductor light emitting element on the substrate inside the frame of the adhesion pattern;
applying an adhesive to the adhesion pattern; and
mounting a cap on the adhesive to accommodate the semiconductor light emitting element, wherein
in the applying the adhesive to the adhesion pattern, the adhesive is applied to the adhesive pattern so as to penetrate into the pattern through hole.

13. The method according to claim 12, further comprising:
curing the adhesive exposed from the substrate through hole by irradiating the adhesive exposed from the substrate through hole with an ultraviolet ray; and
curing entirety of the adhesive.

14. The method according to claim 13, wherein
the substrate through hole is one of multiple substrate through holes,
the pattern through hole is one of multiple pattern through holes, and
in the curing the adhesive exposed from the substrate through hole, the adhesive exposed from the multiple substrate through holes is simultaneously irradiated with the ultraviolet ray.

15. The method according to claim 13, wherein the ultraviolet ray is emitted toward the substrate back surface.

16. The method according to claim 13, wherein in the curing entirety of the adhesive, the adhesive is thermally cured.

17. The method according to claim 13, wherein in the curing entirety of the adhesive, the adhesive is cured by being irradiated from the cap with an ultraviolet ray.

18. The method according to claim 12, wherein in the applying the adhesive to the adhesion pattern, the adhesive is applied to the adhesion pattern so as to penetrate into the substrate through hole through the pattern through hole.
